(19) United States
(12) Patent Application Publication
(10) Pub. No.: US 2026/0245842 A1
(43) Pub. Date: Aug. 20, 2026

(54) SEMICONDUCTOR PROCESSING TOOL WITH RF-TRANSMISSIVE DOME STRUCTURE AND DYNAMIC COOLING SYSTEM & METHOD FOR MANUFACTURING RF-TRANSMISSIVE DOME STRUCTURE

(71) Applicant: Lam Research Corporation, Fremont, CA (US)

(72) Inventors: Tongtong Guo, Lake Oswego, OR (US); Madison Wren Zeng, Portland, OR (US); Rachel E. Batzer, Tigard, OR (US); Mohan Thilagaraj, Tualatin, OR (US); Pratyush Rawal, Sherwood, OR (US); Spencer Lorenzo Broderick, Yamhill, OR (US); Joshua Michael Maceachern, Tualatin, OR (US); Prasanna Kulkarni, Tigard, OR (US); Bo Gong, Sherwood, OR (US); Ching-Yun Chang, West Linn, OR (US); Shawn Fiedler, Tigard, OR (US); Michael Keith Mapston, Beaverton, OR (US); Jacob Lee Hiester, Newberg, OR (US); Vineeth Bangera, Bangalore (IN); John Michael Wiltse, Lake Oswego, OR (US)

(21) Appl. No.: 19/149,658

(22) PCT Filed: Jan. 22, 2024
(86) PCT No.: PCT/US2024/012326

§ 371 Date: Jul. 21, 2025

Related U.S. Application Data
(60) Provisional application No. 63/480,985, filed on Jan. 22, 2023.

(51) Int. Cl. H01J 37/32; H10P 72/70

(52) U.S. Cl. CPC H01J 37/32834; H01J 37/32137; H01J 37/32522; H01J 37/32899; H01J 2237/002; H01J 2237/335; H10P 72/70

(57) ABSTRACT

This disclosure provides for improvements to semiconductor processing tools that feature radio-frequency transmissive dome structures that may be used in the generation of plasmas that may then be flowed onto semiconductor wafers. Such improvements may include a cooling system that is configured to cool such dome structures. The cooling system may be switchable between at least two different cooling modes—one in which the cooling system cools the dome structures at a first rate and another in which the cooling system cools the dome structures at a second rate that is lower than the first rate.

### RELATED APPLICATION(S)

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

In some semiconductor processing tools, one or more process stations may be provided that may be used to house semiconductor wafers during wafer processing operations. Such process stations may, for example, be equipped with some form of wafer support that may be used to support a semiconductor wafer during processing operations. In many such semiconductor processing tools, one or more process gases may be distributed across such semiconductor wafers via showerheads or other gas distribution systems.

In some such semiconductor processing tools, the gas distribution system may include a faceplate that is topped with a dome structure that is transmissive to radio-frequency (RF) energy. One or more RF coils may extend around, and be positioned proximate, the dome structure. The RF coils may be used to direct RF energy into the volume enclosed by the dome structure and the faceplate; if such energy is directed into this volume while process gas or process gases are present within the volume, such energy may be used to strike a plasma within the volume that may then be flowed out of the volume, through the faceplate, and onto the wafer (which may be positioned beneath the faceplate).

The present disclosure provides for various improvements to semiconductor processing tools equipped with such dome structures.

### SUMMARY

Details of one or more implementations of the subject matter described in this specification are set forth in the accompanying drawings and the description below. Other features, aspects, and advantages will become apparent from the description, the drawings, and the claims.

In some implementations, an apparatus may be provided that may include one or more process stations. Each process station may include an enclosure defining a cooling volume and a dome structure including a radio-transmissive material, having an inlet as well as an outlet opposite the inlet, and located within the cooling volume of the enclosure of that process station. Each station may also include one or more radio frequency (RF) coils that extend around the dome structure of that process station, a faceplate positioned underneath the dome structure of that process station and proximate the outlet of the dome structure of that process station, and a wafer support positioned such that the faceplate of that process station is interposed between the wafer support of that process station and the dome structure of that process station. The apparatus may also include a cleaning plasma distribution system configured to facilitate direction of a cleaning plasma onto the wafer support or wafer supports of the one or more process stations and an RF power system configured to be operable in different power modes, the different power modes including a first power mode and a second power mode. The RF power system, in the first power mode, may also provide at least a first level of RF power to the RF coil or RF coils of the one or more process stations, and, in the second power mode, may provide a second level of RF power to the RF coil or RF coils of the one or more process stations. The second level of RF power may be less than the first level of RF power. The apparatus may further include a cooling system configured to be operable in different cooling modes, the different cooling modes including a first cooling mode and a second cooling mode. The cooling system, in the first cooling mode, may cool the dome structure or dome structures of the one or more process stations at a first rate and using a cooling fluid, and may, in the second cooling mode, cool the dome structure or dome structures of the one or more process stations at a second rate lower than the first rate and using the cooling fluid. The apparatus may also include a controller configured to cause the apparatus to be operable in different operational modes, the different operational modes including at least a first operational mode and a second operational mode. The controller, when causing the apparatus to be operable in the first operational mode, may cause the RF power system to be in the first power mode and may cause the cooling system to be in the first cooling mode, and, when causing the apparatus to be operable in the second operational mode, may cause the cleaning plasma distribution system to direct the cleaning plasma onto the one or more wafer supports of the one or more process stations and may cause the cooling system to be in the second cooling mode.

In some implementations, the apparatus may further include a flow modulation system configured to be operable in different flow states, the different flow states including a first flow state and a second flow state. The cooling system may include an exhaust system interface and one or more conduits, each conduit fluidically interposed between the exhaust system interface and the cooling volume defined by the enclosure of a corresponding one of the one or more process stations, wherein the exhaust system interface may be configured to be connected with a facility exhaust system. The flow modulation system, in the first flow state, may permit up to a first level of fluid flow from the cooling volume or cooling volumes defined by the enclosure or enclosures of the one or more process stations and through the exhaust system interface via the one or more conduits, and may, in the second flow state, permit up to a second level of fluid flow from the cooling volume or cooling volumes defined by the enclosure or enclosures of the one or more process stations and through the exhaust system interface via the one or more conduits. The second level of fluid flow may be less than the first level of fluid flow. The controller in such an apparatus may, when causing the apparatus to be in the first operational mode, be configured to cause the flow modulation system to be in the first flow state, and may, when causing the apparatus to be in the second operational mode, be configured to cause the flow modulation system to be in the second flow state.

In some implementations, the second level of fluid flow may be 10% or less of the first level of fluid flow. In some further implementations, the second level of fluid flow may be a zero level of fluid flow.

In some implementations, the flow modulation system may include one or more actuators and one or more movable elements, the one or more actuators may be configured to cause the one or more movable elements to move between at least a first position and a second position when actuated, the one or more movable elements, when in the first position, may provide a first level of flow resistance to fluid flow through the one or more conduits, the one or more movable elements, when in the second position, may provide a second level of flow resistance to fluid flow through the one or more conduits, and the second level of flow resistance may be higher than the first level of flow resistance. The controller, when causing the apparatus to be in the first operational mode, may control the one or more actuators such that the one or more movable elements are in the first position, and, when causing the apparatus to be in the second operational mode, may control the one or more actuators such that the one or more movable elements are in the second position.

In some implementations, each movable element of the one or more movable elements may be configured so as to at least partially block a flow path through at least one of the one or more conduits when in the second position.

In some implementations, each movable element of the one or more movable elements may be configured so as to completely block a flow path through at least one of the one or more conduits when in the second position.

In some implementations, the flow modulation system may include one or more vent ports, each vent port leading to an alternate flow path separate from the flow path or flow paths through the one or more conduits. In such implementations, each movable element of the one or more movable elements may be configured so as to at least partially block at least one of the alternate flow paths when in the first position and to block that at least one of the alternate flow paths to a lesser extent when in the second position.

In some implementations, the flow modulation system may include one or more vent ports, each vent port leading to an alternate flow path separate from the flow path or flow paths through the one or more conduits, and each movable element of the one or more movable elements is configured so as to completely block at least one of the alternate flow paths when in the first position and to not block that at least one of the alternate flow paths when in the second position.

In some implementations, the one or more vent ports may be fluidically interposed between the exhaust system interface and an ambient environment, and the one or more alternate flow paths may lead to the ambient environment.

In some implementations, each movable element may be a shutter.

In some implementations, the flow modulation system may be located in the exhaust system interface.

In some implementations, the one or more process stations may include multiple process stations, the exhaust system interface may include a housing having one or more walls with one or more first openings and one or more second openings, each first opening leading to one of the conduits and each second opening serving as one of the one or more vent ports or as a vent port, and the one or more movable elements may include a movable element that is a shutter that is sized so as to block all of the one or more second openings and none of the one or more first openings when in the first position and so as to block all of the one or more first openings and none of the one or more second openings when in the second position.

In some implementations, each enclosure may have one or more first apertures and one or more first fans, each first fan may be positioned proximate to one of the first apertures, the controller may be configured to cause the one or more first fans of each enclosure to operate at a first fan speed when causing the apparatus to be in the first operational mode and to cause the one or more first fans of each enclosure to operate at a second fan speed when causing the apparatus to be in the second operational mode, and the second fan speed may be lower than the first fan speed.

In some implementations, the second fan speed may be 10% or less of the first fan speed. In some further implementations, the second fan speed may be zero.

In some implementations, each enclosure may have one or more first apertures, one or more first fans, and one or more fan shutters. Each first fan may be positioned proximate to one of the first apertures, each fan shutter may be configured to be movable between a first configuration and a second configuration to adjust a volumetric flow of the cooling fluid into the cooling volume of the enclosure of which that fan shutter is part of, each fan shutter, in the first configuration, may permit up to a first level of the volumetric flow of the cooling fluid, and, in the second configuration, may permit up to a second level of the volumetric flow of the cooling fluid, and the first level of the volumetric flow may be larger than the second level of the volumetric flow. The controller may be configured to cause the one or more fan shutters be in the first configuration when causing the apparatus to be in the first operational mode, and further configured to cause the one or more fan shutters be in the second configuration when causing the apparatus to be in the second operational mode.

In some implementations, the second level of the volumetric flow may be 10% or less of the first level of the volumetric flow. In some further implementations, the second level of the volumetric flow may be zero.

In some implementations, each enclosure may have one or more inlet-outlet apertures and one or more reversible-direction fans, each reversible-direction fan may be positioned proximate to one of the inlet-outlet apertures and configured to direct the cooling fluid through the inlet-outlet aperture proximate thereto in a first direction when caused to operate in a first directional mode and to direct the cooling fluid through the inlet-outlet aperture proximate thereto in a direction opposite the first direction when caused to operate in a second directional mode, the controller may be configured to cause the one or more reversible-direction fans to operate in the first directional mode when causing the apparatus to be in the first operational mode, and the controller may be configured to cause the one or more reversible-direction fans to operate in the second directional mode when causing the apparatus to be in the second operational mode.

In some implementations, the cooling system may include one or more heaters configured to be operable in different heating states, the different heating states including a first heating state and a second heating state. Each heater may be associated with one of the one or more process stations and may be configured to deliver a first amount of heating power to the dome structure of that process station when in the first heating state and a second amount of heating power to the dome structure of that process station when in the second heating state, the first amount of heating power may be less than the second amount of heating power, and the controller is configured to cause the one or more heaters to be in the first heating state when the cooling system is in the first cooling mode and in the second heating state when the cooling system is in the second cooling mode.

In some implementations, the cooling system may include one or more heaters configured to be operable in different heating states, the different heating states including a first heating state and a second heating state, each heater may be associated with one of the one or more process stations and may be configured to deliver, when in a first heating state, a first amount of heating power to the cooling fluid before the cooling fluid is flowed through the cooling volume of that process station and, when in a second heating state, a second amount of heating power to the cooling fluid before the cooling fluid is flowed through the cooling volume of that process station. The first amount of heating power may be less than the second amount of heating power, and the controller may be configured to cause the one or more heaters to be in the first heating state when the cooling system is in the first cooling mode and in the second heating state when the cooling system is in the second cooling mode.

In some implementations, the first amount of heating power may be 10% or less of the second amount of heating power. In some further implementations, the first amount of heating power may be zero.

In some implementations, the cooling fluid may be air. In some further such implementations, the cooling fluid source may be ambient air.

In some implementations, the second level of RF power may be a zero power level. In some implementations, the second rate may be a zero rate.

In some implementations, an apparatus may be provided that includes a dome structure having a flange portion extending radially outward from a sidewall of the dome structure. The dome structure may include one or more silicon oxide materials, the flange portion may have a top surface and a bottom surface on a side opposite the top surface, and a majority of the dome structure may have a first transmissivity to ultraviolet light and at least the top surface and the bottom surface may have a second transmissivity to ultraviolet light that is lower than the first transmissivity to ultraviolet light.

In some implementations, the flange portion may include a sub-portion including a first silicon oxide material that has the first transmissivity to ultraviolet light, the sub-portion may be covered on top and bottom with a second silicon oxide material that has the second transmissivity to ultraviolet light, and the second silicon oxide material may provide the top surface and the bottom surface.

In some implementations, the second silicon oxide material may be optically opaque to ultraviolet light.

In some implementations, the second silicon oxide material may have microbubbles distributed within it.

In some implementations, the second silicon oxide material may be provided by thin annular rings including the second silicon oxide material that are fused to the top and bottom of the sub-portion.

In some implementations, a majority of the dome structure, inclusive of the sidewall, may include a first silicon oxide material having the first transmissivity to ultraviolet light, the flange portion may include a second silicon oxide material having the second transmissivity to ultraviolet light, and the flange portion is a separate component that is fused to the sidewall.

In some implementations, the apparatus may further include a faceplate, a collar, a first seal, and a second seal. The first seal may be compressed between the faceplate and the bottom surface of the flange portion, and the second seal may be compressed between the collar and the top surface of the flange portion.

In some implementations, the faceplate may have a plurality of gas distribution ports extending therethrough.

In some implementations, the first seal and the second seal may be elastomeric seals.

In some implementations, the collar may be a multi-piece collar including multiple segments that encircle the dome structure proximate the flange portion.

In some implementations, the faceplate may include one or more internal cooling passages that are proximate to the first seal.

In some implementations, the one or more internal cooling passages may be each arranged so as to follow an arcuate or circular path within the faceplate.

In some implementations, the bottom surface of the flange portion may provide a bottommost surface of the dome structure.

In some implementations, a method may be provided that includes manufacturing a silicon oxide dome structure having an inlet as well as an outlet opposite the inlet, and etching at least an interior surface of the dome structure to remove at least a first amount of silicon oxide material prior to installation of the dome structure in a semiconductor processing tool.

In some such implementations, the first amount may be 0.0003″.

In some such implementations, the first amount may be 0.0005″.

In some such implementations, the first amount may be 0.0007″.

In some such implementations, the first amount may be 0.0009″.

In some such implementations, the first amount may be 0.001″.

In some such implementations, the method may further include subjecting at least the interior surface of the dome structure to a flame-polishing operation prior to the etching of at least the interior surface of the dome structure.

In some such implementations, the etching may be performed by exposing at least the interior surface of the dome structure to a gas containing one or both of atomic fluorine and hydrogen fluoride.

In some such implementations, the etching may be performed by exposing at least the interior surface of the dome structure to a liquid containing hydrogen fluoride.

### BRIEF DESCRIPTION OF THE DRAWINGS

Reference to the following Figures is made in the discussion below; the Figures are not intended to be limiting in scope and are simply provided to facilitate the discussion below.

FIG. 1 depicts a schematic of an example apparatus having dome structures.

FIG. 2 depicts a schematic of a variant of the example apparatus of FIG. 1.

FIG. 3 depicts a schematic of another variant of the example apparatus of FIG. 1.

FIG. 4 depicts a schematic of a further variant of the example apparatus of FIG. 1.

FIG. 5 depicts a schematic of an additional variant of the example apparatus of FIG. 1.

FIG. 6 depicts a schematic of yet another variant of the example apparatus of FIG. 1.

FIG. 7 depicts a detail view of the rectangular region 7 in FIG. 1.

FIG. 8 depicts a top view of a multi-segment collar clamping a dome structure.

FIG. 9 depicts a top view of a collar that is a contiguous ring and that has a single internal cooling passage.

FIG. 10 depicts another example variant with a flange portion that is a separate piece that is bonded or fused to the remainder of a dome structure.

FIG. 11 depicts an example in which a faceplate has cooling passage(s).

FIGS. 12 through 16 depict various stages in a manufacturing process for a dome structure according to this disclosure.

FIG. 17 depicts a flow diagram for an example manufacturing process for making a dome structure according to this disclosure.

The above-described Figures are provided to facilitate understanding of the concepts discussed in this disclosure and are intended to be illustrative of some implementations that fall within the scope of this disclosure but are not intended to be limiting-implementations consistent with this disclosure and which are not depicted in the Figures are still considered to be within the scope of this disclosure.

### DETAILED DESCRIPTION

As discussed above, this disclosure provides for improvements to semiconductor processing tools that feature RF-transmissive dome structures that may be used in the generation of plasmas that may then be flowed onto semiconductor wafers.

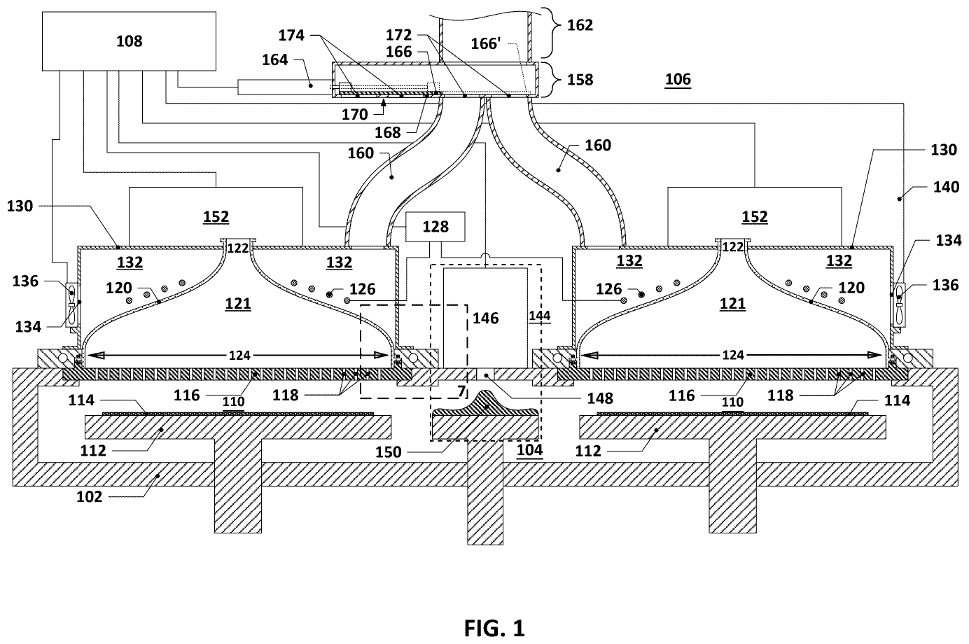

FIG. 1 depicts a diagram of an apparatus, e.g., an example semiconductor processing system, having RF-transmissive dome structures. As can be seen in FIG. 1, an apparatus 100 is depicted that includes a chamber 102 that serves to isolate a processing volume 104 from a surrounding ambient environment 106. The chamber 102 may be configured to support wafer processing operations for one or more semiconductor wafers 114 (also referred to herein as simply “wafers”), which may be supported within the chamber 102 on corresponding wafer supports 112. Generally speaking, the apparatus 100 may include one or more process stations 110, each of which may have a wafer 114 located within it during wafer processing operations.

Some semiconductor processing tools may have a single process station, i.e., be configured to only process one wafer 114 at a time, while others, such as the apparatus 100, may have multiple process stations 110. In some implementations having multiple process stations, such as that pictured, the process stations 110 may be configured such that the wafers 114 reside within a contiguous internal volume of the chamber 102, i.e., the wafers 114 share a generally common pressure environment. In other implementations, however, a semiconductor processing tool having multiple process stations 110 may have multiple chambers 102 that may be isolatable from one another, e.g., via slit valves or other valve/door mechanisms, with each such chamber 102 having one or more process stations 110 associated therewith. The apparatus 100, in this example, is a quad-station implementation, in which four process stations 110 are arranged in a circular array. The wafers 114 may be transferred between the process stations 110, for example, using an indexer or other system (not pictured).

Regardless, each process station 110 of the apparatus 100 may include a wafer support 112 that is configured to support one of the wafers 114 thereupon. The wafer support 112 may be any structure that is configured to provide support to the wafer 114 during wafer processing operations. In some instances, the wafer support 112 may include a vacuum chuck or electrostatic chuck that may be used to clamp the wafer 114 in place during wafer processing operations. The wafer support 112 may also, in some implementations, include or act as an electrode for the purposes of providing RF power to gases that may be present above the wafer 114. The wafer support 112 may, in some cases, include heating and/or cooling systems, purge gas distribution systems to distribute an inert (or chemically non-reactive) species of gas to the back side of the wafer 114, and/or other features that may facilitate wafer processing operations.

The process stations 110 may also each include a gas distribution system that is located above the wafer support 112. The gas distribution system may include a dome structure 120 and a faceplate 116 that may include one or more sets of gas distribution ports 118 that exit a bottom surface thereof. The dome structure 120 may be made of an RF-transmissive material, e.g., a dielectric such as quartz (silicon oxide), aluminum oxide, or aluminum nitride, and may feature an inlet 122 and an outlet 124. For clarity, it will be understood that the RF-transmissive material is a material that has a dielectric loss tangent of less than 0.001 at room temperature. The inlet 122 of the dome structure 120 may generally be much smaller than the outlet 124 of the dome structure and may serve as the introduction point for one or more process gases that are to be flowed into the dome structure 120 in support of wafer processing operations. The outlet of the dome structure 120 may generally be much larger, e.g., having a diameter that is the same size as or larger than the diameter of the wafer 114. For a given process station, the faceplate 116 may be positioned underneath the dome structure 120 and proximate to the outlet 124, interposed between the faceplate 116 and the dome structure 120 of that process station 110. Thus, each dome structure 120 and the faceplate 116 positioned therebeneath may form an enclosed volume that may be used to support plasma generation operations.

For example, each process station 110 may have one or more RF coils 126 that may extend at least partially around the dome structure 120 of that process station 110. The RF coils 126 may be connected with an RF power system 128 that is configured to be operable in different power modes so as to provide different levels of RF power to the RF coils in each power mode. For example, the RF power system 128 may be configured to be switchable between a first power mode and a second power mode, with the amount or level of RF power that is supplied to the RF coils 126 in the first power mode being higher than that supplied to the RF coils 126 in the second power mode. The amount or level of power provided to the RF coils 126 may be selected so as to cause plasmas to be generated within the enclosed volumes between the dome structures 120 and the faceplates 116 when a suitable process gas is present within the enclosed volumes.

At least one set of the gas distribution ports 118 that exit the bottom surface of the faceplate 116 may be through-holes that extend through the faceplate 116, thereby allowing for fluidic communication between the enclosed volumes between the dome structures 120 and the faceplates 116. This allows the plasmas that may be generated within such enclosed volumes to be flowed onto the wafers 114 in support of wafer processing operations.

In some implementations, the faceplate 116 may also include one or more additional sets of gas distribution ports. The gas distribution ports in each such additional set of gas distribution ports may be blind holes leading to a corresponding gas distribution plenum located internally within the faceplate 116. Such additional sets of gas distribution ports may be used to provide one or more different process gases to the process regions in between the faceplates 116 and the wafers 114, if desired.

The apparatus 100 may also include a cleaning plasma distribution system 144 that is configured to distribute a cleaning plasma to the stations 110. For example, the plasma that is generated within the enclosed volumes between the dome structures 120 and the faceplates 116 may, in some cases, be used in support of deposition operations, resulting in various interior surfaces of the apparatus 100, such as surfaces of the chamber 102, the wafer supports 112, and the faceplates 116 gradually having films deposited thereon as a side effect of deposition operations that are performed on the wafers 114.

Such side-effect films may be undesirable, as they may accumulate and start to alter the geometry of features within the chamber 102 and may also serve as particle sources that may generate particulates that can contaminate the wafers 114. Accordingly, it may be desirable to perform periodic cleaning operations to remove such accumulated deposition side-effect material. Such cleaning operations may be performed by flowing a cleaning plasma across the surfaces having such films, such as that which may be generated and distributed using the cleaning plasma distribution system 144. In the depicted implementation, the cleaning plasma distribution system 144 includes a remote plasma source or generator 146 that is connected with a plasma inlet 148 located in the center of the chamber 102. When cleaning operations are to be performed, plasma from the remote plasma source or generator 146 may be flowed into the chamber 102 via the plasma inlet 148. The stream of cleaning plasma may then impinge on a deflector 150 that may be positioned in the center of the circular array of process stations 110. For example, the deflector 150 may be mounted to the top of a central hub for an indexer system. The deflector 150 may redirect the cleaning plasma flow which is directed downward out of the plasma inlet 148 radially outward such that it flows across the wafer supports 112 and the undersides of the faceplates 116 and eventually impinges on the walls of the chamber 102.

It will be understood that there may be a variety of different types of cleaning plasma distribution systems 144 that may be used in apparatuses such as are described herein. In some implementations, the cleaning plasma distribution system 144 may have a dedicated remote plasma source or generator 146 for each process station 110. In other implementations, the cleaning plasma may be delivered from a common remote plasma source or generator 146 to the process stations 110 via separate dedicated plasma inlets 148, as opposed to through a single plasma inlet 148.

Generally speaking, the cleaning plasma distribution system 144 is a separate plasma generation system from that used to generate the plasmas used for wafer processing operations, e.g., using the RF coils 126. This is due to the fact that the amount of incidental deposition that occurs within the enclosed volumes between the faceplates 116 and the dome structures 120 may be much lower than that which occurs on the wafer support 112, the underside of the faceplate 116, and the chamber 102 walls. Thus, it may be generally more desirable to flow the plasma onto such surfaces in a relatively direct manner, with little in the way of flow obstructions. Flowing such a cleaning plasma through the faceplates 116 would result in a large portion of the cleaning plasma impinging on the upper surfaces of the faceplates 116, reducing the amount of such cleaning plasma that is available to clean the surfaces of the wafer supports 112, the chamber 102 walls, and the undersides of the faceplates 116.

Moreover, generating the cleaning plasma within the enclosed volumes between the faceplates 116 and the dome structures 120 would mean that the dome structures 120 would be exposed to the cleaning plasma at its most energetic state. The gases used for the cleaning plasma, e.g., NF3, may be selected so as to etch away the accumulated incidental films that are to be cleaned. The cleaning plasma may, if generated within the dome structures 120, would etch away the material of the dome structure at a relatively rapid rate, requiring that the dome structures 120 be replaced at much more frequent intervals.

By keeping the cleaning plasma distribution system 144 separate from the plasma generation system provided using the RF coils 126 and the enclosed volume between the faceplates 116 and the dome structures 120, the cleaning plasma may be directed at the surfaces requiring the most cleaning without subjecting the dome structures 120 to unnecessary exposure to the cleaning plasma at its most energetic state.

While the cleaning plasma may not be generated within or flowed through the enclosed volumes between the faceplates 116 and the dome structures 120, some of the cleaning plasma that is directed into the spaces between the faceplates 116 and the wafer supports 112 may nonetheless flow upward, through the gas distribution ports 118, and into the enclosed volumes of the process stations 110. While such flows of plasma may be counteracted, or at least somewhat mitigated, by flowing a non-reactive purge gas into the enclosed volumes via the inlets 122 of the dome structures 120 so as to push against any cleaning plasma that attempts to flow upward through the gas distribution ports 118, it may still be desirable to permit some small amount of such cleaning plasma to enter the enclosed volumes as well in order to wholly or partially remove any deposition films that may have deposited on the interior surface of the dome structure 120 or the upper surface of the faceplate 116.

In systems such as that depicted in FIG. 1, the generation of a plasma for the processing of wafers 114 within the enclosed volumes between the faceplates 116 and the dome structures 120 may result in a significant amount of heat generation within the enclosed volumes. Left unmitigated, such heat generation will cause thermal expansion cracks in the material of the dome structures 120 and/or other structural damage to the dome structures 120. In order to address such issues, the apparatus 100 may also include a cooling system that is configured to remove heat from the dome structures 120 or portions thereof, thereby limiting the potential temperature increase experienced by the dome structures 120 and preventing, or at least mitigating to some extent, the potential damage that may occur to the dome structures 120 due to the heat produced by the plasma that may be generated within the enclosed volumes between the dome structures 120 and the faceplates 116.

The cooling system may generally be configured to circulate or flow a cooling fluid, e.g., ambient air, past the dome structures 120, thereby allowing heat to be transported away from the dome structures 120 via convection. For the purposes of the remaining discussion, the cooling fluid is assumed to be ambient air (or simply “air”), but it will be understood that other cooling fluids may be used if desired and available. Thus, reference to “air” or “ambient air” should be understood to also indicate reference to other cooling fluids as well.

In some implementations, the cooling system may be designed to induce movement of cooling fluid, at least in part, using equipment that is not part of the apparatus 100. For example, the apparatus 100 may be configured to interface with one or more systems that provide or receive various fluids from the apparatus 100. Such systems may be integrated into a facility where the apparatus 100 is to be installed and may include, but are not limited to, clean dry air (CDA) supply systems that may provide a continuous supply of pressurized, clean, dry air via an outlet, water supply systems that may provide a continuous supply of water, electrical power distribution systems that may provide electrical power at a particular voltage and current level, and exhaust systems that are configured to suction fluids from various points on the apparatus 100. For example, some exhaust systems may be configured to evacuate gases from within the chamber 102 and direct such gases into abatement systems that may be used to neutralize or otherwise render safe any potentially harmful chemical species that may be present. Other exhaust systems may simply be used for cooling of equipment and may be used to draw a cooling fluid, e.g., air, through various portions of the apparatus 100 before transporting such cooling fluid to a remote location where it is vented to atmosphere (potentially with or without further treatment, e.g., filtration).

Cooling systems that are connected with exhaust systems and that use the exhaust system to drive, at least in part, the flow of cooling fluid past the dome structures 120 may provide multiple advantages. For example, such an exhaust system may be used drive, at least in part, cooling fluid flow for multiple apparatuses 100, allowing a single fan or set of fans for the exhaust system to provide cooling for multiple different apparatuses 100. This avoids the need for each apparatus 100 to have a dedicated exhaust system (and the hardware needed to suction cooling fluid from the apparatus) for each apparatus 100. An additional benefit is that the cooling fluid that is drawn into an exhaust system often exits the exhaust system at a location that is distant from the apparatus 100, e.g., at a location that is external to the facility in which the apparatus 100 may be used. This prevents the heat that may be transferred to the cooling fluid from being immediately reintroduced into the ambient air within the facility (or at least the ambient air in the vicinity of the apparatus), where it may heat up the ambient air and reduce the cooling efficiency of the ambient air were the ambient air to then be flowed past the dome structures 120. Yet another benefit that may accrue from the use of such facility exhaust systems is that the amount of noise that may be generated by the apparatus 100 may be much less since the apparatus 100 would not require any or as many fans as would be required if the apparatus 100 itself were to be configured to cause the flow of cooling fluid entirely by itself.

While the cooling system may prevent damage to the dome structures during the generation of plasma within the enclosed volumes between the dome structures 120 and the faceplates 116, such cooling may actually have a detrimental effect during periods of time during which the cleaning plasma is being flowed. As discussed earlier, some of the cleaning plasma may be permitted to flow into the enclosed volume between the dome structures 120 and the faceplates 116, e.g., via the gas distribution ports 118, during cleaning operations in order to remove films that may have deposited on the interior surfaces of the dome structures 120 and/or the upper surfaces of the faceplates 116. It was found, however, that the cleaning efficacy of the cleaning plasma within the enclosed volume between the dome structures 120 and the faceplates 116 was significantly reduced if the dome structures 120 were cooled by the cooling system while cleaning operations were performed. Moreover, the cleaning efficacy may, in some instances, decrease non-uniformly, e.g., if the cooling system cools some portions of the dome structure more effectively than other portions, the cleaning efficacy may be correspondingly less with respect to films deposited on regions of the dome structures subjected to more cooling as compared with films deposited on regions of the dome structures subjected to less cooling.

Film residues that are not able to be cleaned from the interior surfaces of the dome structures, e.g., due to decreased cleaning efficacy of the cleaning plasma, may serve as sources for particulates during later processing operations. Such particulates may then pass through the gas distribution ports 118 and fall onto the wafer 114, contaminating it.

One potential technique for addressing this reduced cleaning plasma efficacy is to simply increase the length of time that the cleaning plasma is resident within the enclosed volumes to offset the reduced efficacy of the cleaning plasma. However, this increases the overall duration of the cleaning process, resulting in reduced wafer through-put and decreasing the profitability of the apparatus 100. Additionally, the cleaning plasma is actually performing an etch process on the interior surface of the dome structures 120, removing whatever material forms the innermost surface of the dome structures 120. If the dome structures 120 are cooled non-uniformly, the cleaning plasma will etch away the innermost surface layers of the dome structures 120 in the warmer portions of the dome structures at a faster rate than in the colder portions of the dome structures 120. As a result, the film that is deposited on the warmer portions of the dome structures 120 may tend to be removed more quickly than the film that is deposited on the colder portions of the dome structures 120, resulting in the underlying material of the dome structures 120 (underneath the films) in the warmer portions of the dome structures 120 becoming completely exposed to the cleaning plasma before the underlying material of the dome structures 120 in the colder portions of the dome structures 120. Accordingly, the cleaning plasma may then start to etch away the dome material itself in the warmer portions of the dome structures 120 while still removing deposited films in the colder portions of the dome structures 120. Over time, this results in the warmer portions of the dome structures 120 being eroded at a greater rate than the colder portions, thereby accelerating the rate at which the dome structures degrade and shortening the overall lifespan of the dome structures.

To address such challenges, the cooling system may be configured to be operable in different cooling modes, including, for example, a first cooling mode and a second cooling mode. The first cooling mode may be used while the apparatus 100 is performing semiconductor processing operations in which a plasma is generated within the enclosed volumes between the dome structures 120 and the faceplates 116. The second cooling mode may be used while the apparatus is performing cleaning operations, e.g., using the cleaning plasma distribution system 144. The cooling system may be configured to cool the dome structures at a first rate while in the first cooling mode and at a second rate that is lower than the first rate while in the second cooling mode. In some instances, the second rate may be 10% or less of the first rate, and in some such instances, the second rate may be a zero rate, i.e., providing no cooling at all (or at least, none attributable to the operation of the cooling system). By having such a cooling system, the apparatus 100 may be able to be operated in wafer processing modes in which plasma is generated within the enclosed volumes between the dome structures 120 and the faceplates 116 without causing thermal damage to the dome structures 120 (or causing less damage thereto) as well as in cleaning modes in which a cleaning plasma is partially directed into the enclosed volumes between the dome structures 120 and the faceplates 116 and is able to clean any accumulated films from the interior surfaces of the dome structures 120 in a more uniform and effective manner than might otherwise be possible.

The apparatus 100 may also include a controller 108 that may be configured to control the various subsystems of the apparatus, e.g., the cleaning plasma distribution system 144, the RF power system 128, the cooling system, and various other systems that may be operated at different times during different operational modes. The controller 108 may, for example, be configured to cause the apparatus 100 to be operable in at least a first operational mode and a second operational mode.

In the first operational mode, the controller 108 may cause the RF power system 128 to be in the first power mode and the cooling system to be in the first cooling mode. In the second operational mode, the controller 108 may cause the cooling system to be in the second cooling mode and the cleaning plasma distribution system to direct the cleaning plasma onto the one or more wafer supports 112 of the one or more process stations 110 and, consequently, into the enclosed volumes between the dome structures 120 and the faceplates 116. In some implementations, the RF power system 128 may also be caused by the controller 108 to be in the second power mode when the apparatus is in the second operational mode and the cleaning plasma distribution system to not direct the cleaning plasma onto the wafer supports 112 when the apparatus is in the first operational mode.

In the apparatus 100, the cooling system is provided by way of several components or subsystems. For example, the cooling system of the apparatus 100 includes an exhaust system interface 158 that is configured to connect with a facility exhaust system 162 and with a plurality of conduits 160 that each lead to an enclosure 130 that is part of each process station 110. The enclosures 130 may, for example, be sheet metal structures that enclose the dome structures 120 and the RF coils 126, defining cooling volumes 132 within which the dome structures 120 are housed. The enclosures 130 may also act as RF shielding that may act to contain RF energy emitted from the RF coils. The conduits 160 may each be fluidically interposed between one of the cooling volumes 132 and the exhaust system interface 158. In some implementations, each enclosure may support or have mounted proximate thereto a process gas supply system 152, e.g., one or more valves or other flow components that may be controlled so as to supply one or more process gases to the inlets 122 of the dome structures 120.

The enclosures 130 may also be equipped with one or more first apertures 134 that are each positioned proximate to a corresponding first fan 136. The first fans 136 may be configured to flow cooling fluid, e.g., ambient air, into the enclosures 130 via the first apertures 134 while the facility exhaust system 162 suctions the cooling fluid from the enclosures 130.

The dome structures 120 may be positioned such that they are in the flow path of cooling fluid being flowed from the first aperture(s) 134 of each enclosure 130 to the outlet of each enclosure 130 and thus able to be cooled by the cooling fluid.

The apparatus 100 may include a flow modulation system that may be used to modulate the flow of fluid through the conduits 160. Such flow modulation systems may be used in systems that are connected with exhaust systems such as the facility exhaust system 162 that are generally always on. For example, a single facility exhaust system 162 may provide suction to a number of different apparatuses simultaneously, and may generally be kept in an “always on” state since the timing of when any particular apparatus 100 is in a state in which suction from the facility exhaust system 162 is needed may be unpredictable.

A flow modulation system may be used to allow an individual apparatus 100 to control when (or how much) suction from the facility exhaust system 162 is applied to the various cooling volumes 132. For example, a flow modulation system may be controlled to be operable in different flow states, including, for example, a first flow state and a second flow state. The flow modulation system, in the first flow state, may permit up to a first level of fluid flow from the cooling volumes 132 defined by the enclosures 130 of the process stations 110 and through the exhaust system interface 158 via the one or more conduits 160. Similarly, the flow modulation system, in the second flow state, may permit up to a second level-lower than the first level-of fluid flow from the cooling volumes 132 defined by the enclosures 130 of the process stations 110 and through the exhaust system interface 158 via the one or more conduits 160. Such a flow modulation system may be controlled by the controller 108 to, when causing the apparatus 100 to be in the first operational mode, be in the first flow state and to, when causing the apparatus 100 to be in the second operational state, be in the second flow state. In some implementations, the second level of fluid flow may be 10% or less of the first level of fluid flow, and in some such cases, the second level of fluid flow may be a zero level of fluid flow.

It will be understood that a wide variety of different mechanisms may be used as flow modulation systems and that any suitable mechanism may be used as a flow modulation system. For example, in the apparatus 100, a flow modulation system is provided by way of a movable element 166 that is located within the exhaust system interface 158. The movable element 166, in this example, is a shutter that is positioned proximate a first wall 170 of a housing 168 that is part of the exhaust system interface 158. An actuator 164, e.g., a pneumatic piston actuator, may be provided and configured so as to allow the movable element 166 to be caused to moved between a first position and a second position. It will be understood, however, that such a flow modulation system may also include multiple movable elements 166 and/or multiple actuators 164 as opposed to the single movable element 166 and actuator 164 shown.

In the first position, the movable element may provide a first level of flow resistance to fluid flow through the one or more conduits 160, while in the second position, the movable element may provide a second, higher level of flow resistance to fluid flow through the one or more conduits 160. For example, in the second position, the movable element(s) 166 may at least partially block a flow path (or one or more flow paths) through at least one of the conduits 160. In some such implementations, the movable element(s) 166 may completely block such a flow path or flow paths when the movable element 166 is in the second position.

The controller 108 may be configured to control the actuator 164 such that the movable element 166 is in the first position when causing the apparatus to be in the first operational mode and such that the movable element 166 is in the second position when causing the apparatus to be in the second operational mode.

In FIG. 1, the movable element 166 is in the first position and does not block a plurality of first openings 172 in the first wall 170 of the housing 168 that lead from the interior of the exhaust system interface 158 to the conduits 160. When the movable element 166 is moved from the first position into the second position, which is indicated by the dotted outline indicated by 166′, the movable element 166 completely blocks the first openings 172 but unblocks second openings 174 in the first wall 170 of the housing 168. The second openings 174 may act as vent ports that provide an alternate flow path for suction from the facility exhaust system from the flow paths through the conduits 160. Such alternate flow paths may, for example, lead to the ambient environment surrounding the apparatus 100, e.g., the second openings 174 (or vent ports) may be fluidically interposed between the ambient environment and the exhaust system interface 158 (or at least the interior plenum volume of the exhaust system interface 158). When the movable element 166 is in the first position, the movable element 166 may at least partially block at least one of the alternate flow paths and when the movable element 166 is in the second position, it may block the at least one of the alternate flow paths to a lesser extent. In the apparatus 100, the movable element 166 completely blocks the second openings 174 (vent ports) leading to the alternate flow paths when in the first position and completely unblocks the second openings 174 leading to the alternate flow paths when in the second position. Thus, the suction from the facility exhaust system 162 may be directed entirely to the cooling volumes 132 via the conduits 160 when the movable element 166 is in the first position or entirely to the ambient environment via the vent ports when the movable element is in the second position. When the suction is diverted to the ambient environment, there will be little or no suction applied to the cooling volumes 132, thereby significantly (or completely) eliminating cooling fluid flow through the cooling volumes 132 due to the facility exhaust system 162.

As noted above, the apparatus 100 also features first fans 136 that are positioned proximate to first apertures 134 in the enclosures 130. The first fans 136 may also be controlled by the controller 108 to enter different states during different operational modes of the apparatus 100. For example, the first fans 136 may be controlled to be operable at different fan speeds, e.g., such as a first fan speed and a second fan speed lower than the first fan speed. In some implementations, the second fan speed may be 10% or less of the first fan speed. In some such implementations, the second fan speed may be a speed of zero.

The controller 108 may, for example, control the first fans 136 to operate at the first fan speed when causing the apparatus 100 to be in the first operational mode and to operate at the second fan speed when in the second operational mode. In some such implementations, when the apparatus 100 is in the first operational mode, the facility exhaust system 162 may be fluidically connected with the cooling volumes 132 to draw cooling fluid from the cooling volumes 132 and the first fans 136 may be caused to flow cooling fluid into the cooling volumes 132 to provide cooling to the dome structures 120. Similarly, when the apparatus 100 is in the second operational mode, the facility exhaust system 162 may be fluidically disconnected from the cooling volumes 132 and the first fans may be caused to be still, thereby causing the flow of cooling fluid through the cooling volumes 132 to become stagnant, thereby providing minimal or no cooling of the dome structures 120.

It will be understood that a variety of other configurations of the apparatus 100 may be provided that may provide similar performance, although perhaps with greater or lesser efficacy in terms of how effectively the cooling of the dome structures may be controlled. For example, in some implementations, the movable element 166 may be relocated such that it is located between the conduits 160 and the cooling volumes 132, e.g., each conduit 160 may be equipped with a dedicated movable element 166 that is able to be moved between two positions, with the movable element 166 blocking the flow of cooling fluid from the cooling volume 132 into the conduit 160 when in a first position, and allowing the flow of cooling fluid from the cooling volume 132 into the conduit when in the second position. In some such implementations, each movable element 166 may have its own actuator 164, while in other implementations, multiple movable elements 166 may be actuated by a common actuator 164.

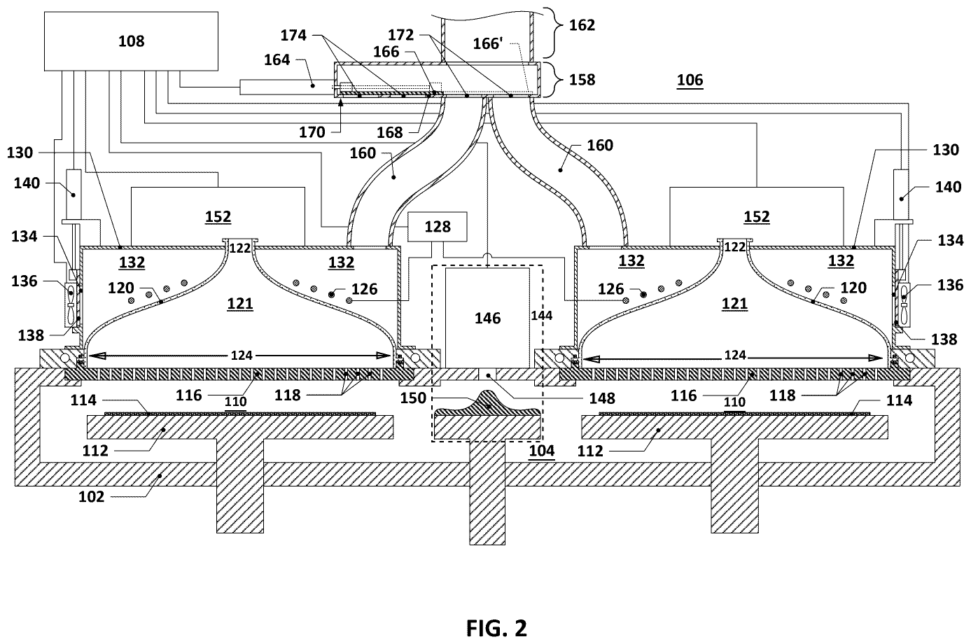

FIG. 2 depicts a variant of the apparatus 100 in which additional movable elements are provided proximate the first fans 136. The apparatus 100 in FIG. 2 is largely identical to that in FIG. 1, and the discussion of the apparatus 100 in FIG. 1 is equally applicable to the apparatus 100 in FIG. 2. However, the apparatus 100 of FIG. 2 also includes fan shutters 138, which are each interposed between one of the first fans 136 and the cooling volume 132 proximate thereto. The fan shutters 138 are each connected with a fan shutter actuator 140, e.g., a linear actuator, such as a pneumatically driven piston, that may be controlled by the controller 108 to be movable between a first configuration and a second configuration to adjust a volumetric flow of the cooling fluid into the cooling volume 132 of the enclosure 130 via corresponding first apertures 134. In the first configuration, the fan shutters 138 may permit up to a first level of the volumetric flow, and in the second configuration, the fan shutters 138 may permit up to a second level of volumetric flow. The first level of volumetric flow may be larger than the second level of volumetric flow. In some such implementations, the second level of volumetric flow may be 10% or less of the first level of volumetric flow and, in some further such cases, may be a zero level of volumetric flow.

In such implementations, the controller may be configured to cause the one or more fan shutters 138 be in the first configuration when causing the apparatus 100 to be in the first operational mode and to cause the one or more fan shutters 138 be in the second configuration when causing the apparatus 100 to be in the second operational mode. In some such implementations, the first fans 136 may be controlled as discussed above with respect to FIG. 1, but in other such implementations, the first fans 136 may be caused to operate in the same manner in both the first and second operational modes (in such cases, the fan shutters 138 may prevent movement of cooling fluid into the cooling volumes 132).

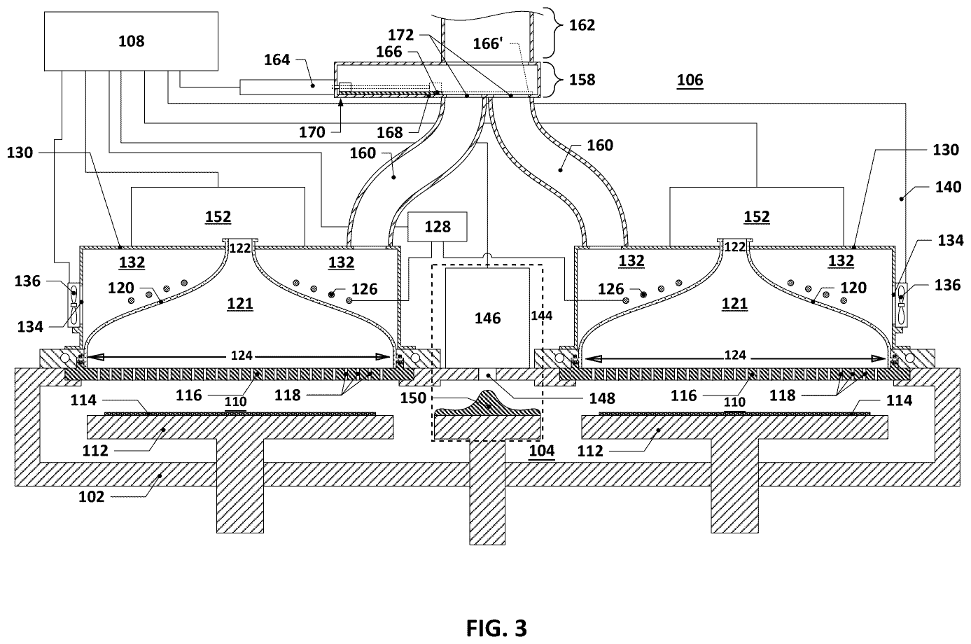

FIG. 3 depicts another variant of the apparatus 100. The apparatus 100 of FIG. 3 is identical to the apparatus 100 of FIG. 1 except that the second openings 174 in the first wall 170 of the housing 168 of the exhaust system interface 158 are omitted. In this implementation, when the movable element 166 is in the second position, i.e., blocking the flow paths through the conduits 160, there are no alternate flow paths available for the suction provided by the facility exhaust system 162 to be applied to. As such, the exhaust system interface 158 is a dead end. The consequent disruption of fluid flow through the exhaust system interface 158 to the facility exhaust system 162 may cause a step change in the amount of suction delivered to other apparatuses 100 (or other systems) that may be connected to the facility exhaust system, which may, in some cases, be undesirable. However, such an approach may also be somewhat quieter than the approach reflected in the apparatus 100 of FIG. 1 since it avoids the use of vent ports that allow the suction to be diverted to the ambient environment.

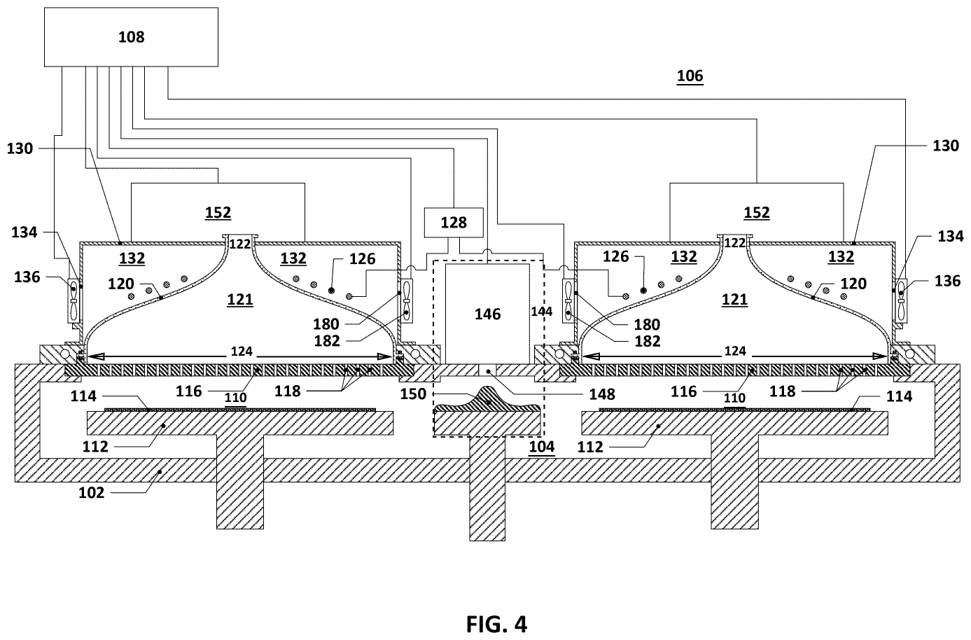

FIG. 4 depicts yet another variant of the apparatus 100 of FIG. 1. In this implementation, the apparatus 100 is not connected with the facility exhaust system 162. Instead, each enclosure 130 is provided with an inlet-outlet aperture 180 and a reversible-direction fan 182 in addition to the first fan 136 and the first aperture 134. Each reversible-direction fan 182 may be positioned proximate to one of the inlet-outlet apertures 180 and be configured to direct the cooling fluid through that inlet-outlet aperture 180 and in a first direction when caused to operate in a first directional mode and to direct the cooling fluid through that inlet-outlet aperture 180 and in a second direction opposite the first direction when caused to operate in a second directional mode.

In such an implementation, the controller 108 may be configured to cause the reversible-direction fans 182 to operate in the first directional mode when causing the apparatus 100 to be in the first operational mode and to cause the one or more reversible-direction fans 182 to operate in the second directional mode when causing the apparatus 100 to be in the second operational mode. In such implementations, the reversible-direction fans 182 may direct cooling fluid out of the cooling volumes 132 when in the first directional mode and may direct cooling fluid into the cooling volumes 132 when in the second directional mode. The first fans 136 and the reversible-direction fans 182 may, for example, be operated so as to provide similar rates of fluid flow of the cooling fluid through the first apertures 134 and the inlet-outlet apertures 180. Thus, when the apparatus 100 is in the first operational mode, the first fans 136 may direct cooling fluid into the cooling volumes 132 and the reversible-direction fans 182 may draw the cooling fluid out of the cooling volumes 132. However, when the apparatus 100 is in the second operational mode, the first fans 136 and the reversible-direction fans 182 may both direct cooling fluid into the cooling volumes 132, causing the flow through the cooling volume to become stagnant and cooling to be reduced or stopped.

In other implementations, the first fans 136 may be operated so as to draw cooling fluid from the cooling volumes 132 and the reversible-direction fans 182 may direct cooling fluid into the cooling volumes 132 when in the first directional mode and may draw the cooling fluid out of the cooling volumes 132 when in the second directional mode. In such implementations, the first fans 136 and the reversible-direction fans 182 may both draw cooling fluid from the cooling volumes 132 when the apparatus 100 is in the second operational mode, thereby similarly causing the flow through the cooling volume to become stagnant and cooling to be reduced or stopped.

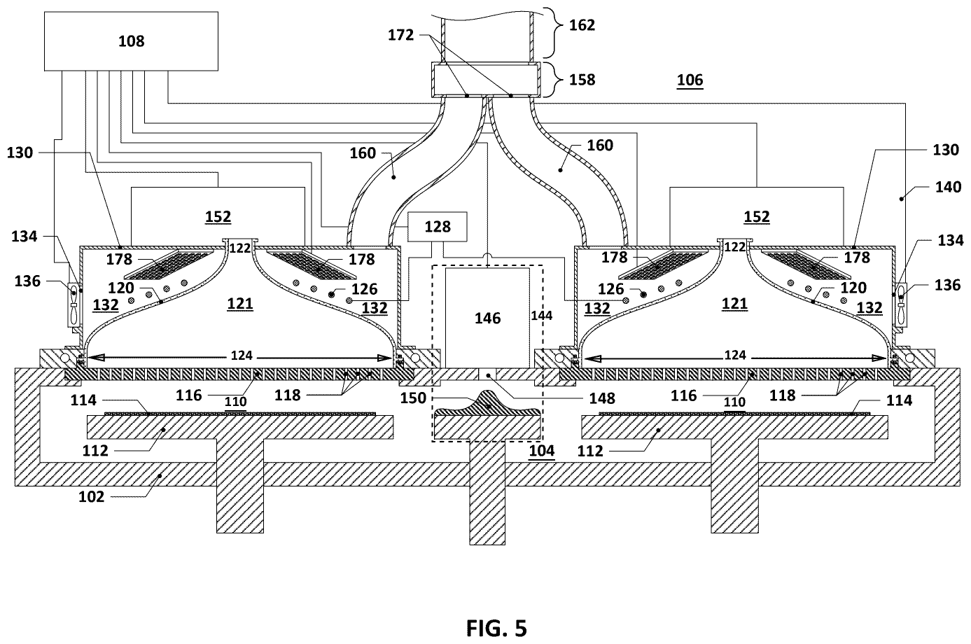

In some cases, the cooling system may include heating elements that may be selectively activated so as to provide heating that at least partially offsets the cooling effect that the cooling system may otherwise provide. FIG. 5 depicts a variant of the apparatus 100 that includes such heating elements. As can be seen in the apparatus 100 of FIG. 5, the cooling system includes an exhaust system interface 158 that has no flow modulation system in it. Thus, there will always be at least some cooling fluid flow through the cooling volumes 132 while the facility exhaust system 162 is operative (which will generally be the case all the time). However, the enclosures 130 in this variant also each house one or more heating elements 178 that are positioned so as to direct heat into the dome structures 120. Any suitable heating elements 178 may be used, although radiant heating may be preferable since it may heat the dome structures 120 more evenly and may be relatively immune to the flow of cooling fluid (convective heat transfer, in contrast, would be largely defeated by the flow of cooling fluid through the cooling volumes 132). In the depicted example, the heating elements 178 are arrays of light-emitting diodes that are configured to direct high-intensity light onto the dome structures 120, thereby providing heat to the illuminated areas. In some such approaches, the placement of such heating elements may be selected such that different regions of the dome structures 120 that experience different amounts of cooling due to the flow of cooling fluid may receive different amounts of heat from the heating elements 178. For example, if particular regions of the dome structures 120 are known to experience greater amounts of cooling than other regions (and thus typically be at a lower temperature than those other regions), the heating elements may be configured to direct more heat into those particular regions and less heat into the other regions, thereby raising the temperature within the particular regions more and causing the temperature differences between the particular regions and the other regions to be decreased. This increases the temperature uniformity within the dome structures 120 and, in turn, may allow cleaning times to be shortened since the particular regions, which would typically take the longest to clean due to their lower temperatures, would have elevated temperatures.

In systems such as the apparatus 100 of FIG. 5, the heating elements 178 (or heaters) may be configured to be operable so as to provide different heating states, for example, a first heating state and a second heating state. As discussed above, each heating element 178 may be associated with one of process stations 110. Each heating element 178 may be configured to deliver a first amount of heating power to the dome structure 120 of the process station 110 in which it is located when in the first heating state and a second amount of heating power to the dome structure 120 of that process station 110 when in the second heating state. The first amount of heating power may be less than the second amount of heating power, e.g., 10% or less of the second heating power or, in some cases, a zero amount of heating power.

In such implementations, the controller 108 may cause the heating elements 178 to be in the first heating state when the cooling system is in the first cooling mode and in the second heating state when the cooling system is in the second cooling mode. Thus, when a plasma is being generated within the dome structures 120, i.e., the apparatus 100 is in the first operational state, the heating elements 178 may be caused to be in a low-power state (which may, in some cases, be an off or zero-power state) so that the cooling system is able to effectively cool the dome structures 120. When the apparatus 100 is instead being operated in a cleaning mode, i.e., in the second operational state, the heating elements 178 may be caused to be in a higher-power state, thereby providing heating to the dome structures 120 that may counteract, at least partially, the cooling provided by the flow of cooling fluid.

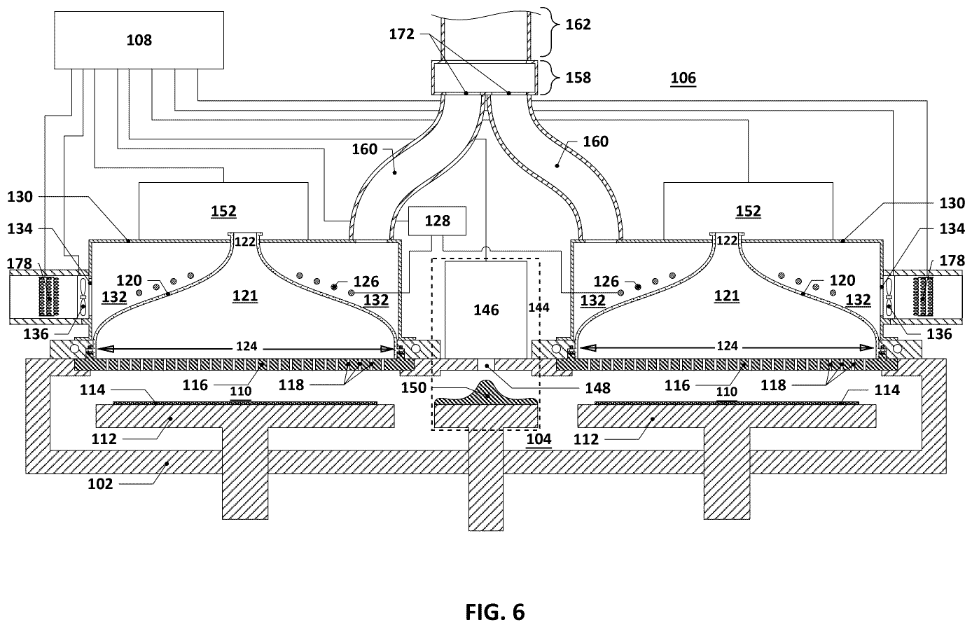

FIG. 6 depicts another example variant of the apparatus 100 that is similar in operation to the apparatus 100 of FIG. 5, except that the heating elements 178 are positioned so as to deliver heat to the cooling fluid before it passes through the first fans 136 and into the cooling volumes 132. For example, each first fan 136 may be connected with a duct or other structure that is equipped with a heating element 178 that is configured so as to heat the cooling fluid. The heating elements 178 may, for example, be resistive coil heaters or other heaters that are suitable for radiant heating of fluids. In such systems, the cooling fluid may be pre-heated before it reaches the dome structures 120 in order to decrease the cooling efficiency of the cooling system, e.g., when the cooling system is operated in the second cooling mode.

It will be understood that the concepts discussed above with respect to any particular example implementation may be reconfigured in different combinations. For example, any apparatus 100 that features a connection to the facility exhaust system 162 may instead replace the connections with the exhaust system with a vent to the ambient environment. Such vents may, in some cases, be equipped with fans (similar to the reversible-direction fans 182 of FIG. 4, but not necessarily reversible) to facilitate cooling fluid flow through the cooling volumes 132. In such cases, the fans may be turned off when the cooling system is in the second cooling mode so that cooling fluid is not actively being drawn through the cooling volumes 132 and turned on when the cooling system is in the first cooling mode (thereby causing the cooling fluid to circulate through the cooling volumes 132). In an alternative implementation, the fans may be equipped with shutters, e.g., similar to the example apparatus 100 of FIG. 2, and the shutters activated to block flow of cooling fluid from the fans when in the second cooling mode and unblock flow of cooling fluid from the fans when in the first cooling mode. Heating elements 178 may also or alternatively be used in such implementations, e.g., similar to their use in the apparatus 100 of FIG. 2.

It will be further understood that while the above examples have focused on implementations in which multiple stations are present, the concepts discussed above are equally applicable to single-station tools, e.g., having a single dome structure 120, in which case some references to elements in the plurality may be replaced with references to a single item.

It will additionally be understood that while the above examples have been directed at apparatuses in which the first cooling mode is engaged when the apparatus is generating a plasma within the dome structures and the second cooling mode is engaged when a cleaning plasma is being provided, other implementations may engage the first and second cooling modes under other corresponding conditions. For example, the first cooling mode may be engaged while the apparatus is performing a first stage of a semiconductor manufacturing process and the second cooling mode may be engaged while the apparatus is performing a second stage of that semiconductor manufacturing process. In other words, the second cooling mode need not necessarily be tied to the performance of a cleaning operation within the apparatus. It will be understood that the apparatuses discussed herein may thus have controllers that are configured to engage the first cooling mode and/or second cooling mode under conditions other than those discussed herein.

In some implementations, the dome structures used in such tools and/or the components in close proximity to such dome structures may be designed in a way that may act to prolong the lifespan of the dome structures. For example, the cleaning plasma that enters, via a faceplate, the enclosed volume between the faceplate and a dome structure will typically have a higher energy density near the faceplate as opposed to at higher elevations within the enclosed volume. As a result, the reactivity of the cleaning plasma may be higher in regions nearer the faceplate as compared with regions further from the faceplate. As a result, the dome structure may be subjected to an increased rate of etching from the cleaning plasma at locations that are closer to the faceplate as compared with further from the faceplate.

Various features may be included, either separately or in combination with each other and/or earlier features discussed herein, in a dome structure or in nearby components in order to reduce the potential for increased etching of the dome structure nearer the faceplate.

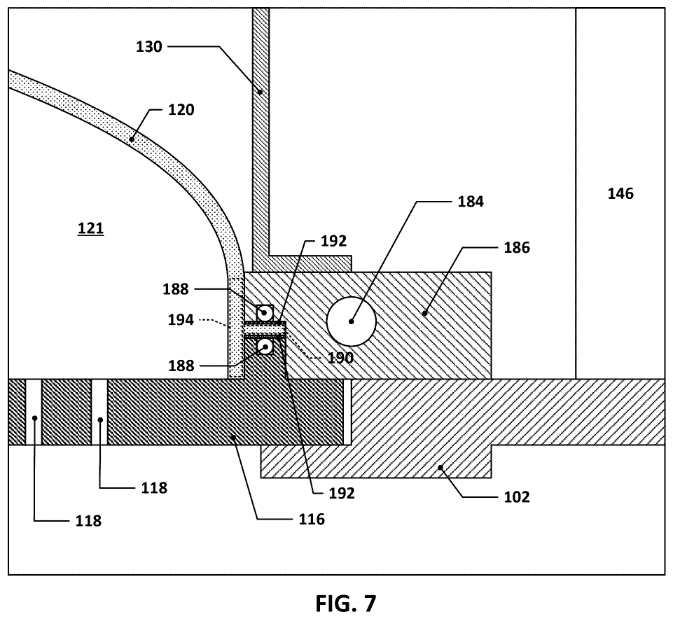

FIG. 7 depicts a detail view of the rectangular region 7 in FIG. 1. As can be seen in FIG. 7, the dome structure 120 has a flange portion 190 that extends radially outward from a vertically oriented (or nearly vertically oriented) sidewall portion 194 of the dome structure 120. The flange portion 190 may have top and bottom surfaces that are in contact with seals 188, e.g., O-ring or other elastomeric seals. The seals 188 may be clamped between the faceplate 116 and a collar 186. The collar 186, for example, may be secured by threaded fasteners (not shown) that may be tightened so as to draw the collar 186 against the chamber 102 and the faceplate 116, thereby clamping the faceplate 116 in place relative to the chamber 102 and also clamping the dome structure 120 in place relative to the faceplate 116.

In some cases, the vertical sidewall and flange of the dome structure 120 may be made as a separate component that is then bonded or fused to the remainder of the dome structure 120. For example, the portion of the dome structure 120 extending from approximately the top of the collar 186 downwards may be made from an opaque quartz material that is then bonded or fused to the remainder of the dome structure 120, which may be made from an optically transparent quartz material. Making the bottom of the dome structure 120, including the flange portion, opaque may shield the seals 188 from exposure to ultraviolet light that may be emitted during plasma generation within the enclosed volume 121. This may prevent the seals 188 from degrading or failing due to material degradation caused by such ultraviolet light exposure. For the purposes of this disclosure, the term “opaque,” as relating to the optical properties of quartz, is to be understood to refer to a material that blocks at least 90% of light in the 100 nm to 400 nm wavelength range per two millimeters of thickness of the material. In some implementations, an optically opaque quartz material may block up to 95% or 99% of light in this wavelength range per two millimeters or per millimeter of thickness of the material.

However, making the bottom portion of the dome structure 120 opaque in this manner may also increase the susceptibility of the bottom portion of the dome structure 120 to chemical attack, e.g., by the cleaning plasma. For example, opaque quartz is produced when microbubbles or other small inclusions are trapped within molten silica that then cools to form quartz. Such microbubbles, however, represent regions within the quartz where there is no material. Each such microbubble therefore offers no resistance to the etching that is performed and thus accelerates the overall etch rate of the dome structure in the region having the microbubbles.

In FIG. 7, the flange portion 190 and the remainder of the dome structure 120 are both made from optically transparent quartz, e.g., as a single contiguous part with a homogenous material composition. This avoids exposing opaque quartz material to the cleaning plasma. In other words, the entire inside surface of the dome structure 120 may be made of optically clear quartz (which does not include microbubbles) and thus not have any regions where the material of the dome structure etches at a faster rate due to not being solid material. However, this means that the flange portion 190 is transmissive to ultraviolet light that may originate from within the enclosed volume 121. In this implementation, the flange portion 190 has an opaque material layer 192 on (or forming) both the top and bottom surfaces thereof. The opaque material layers 192 may, for example, be thin layers, e.g., approximately 3 mm thick (or larger), of optically opaque quartz that are fused or bonded to the top and bottom surfaces of the flange portion 190, thereby providing a barrier to ultraviolet light transmission to the seals 188. The opaque material layers may, in some implementations, be an optically opaque coating that is applied directly to or deposited directly on the top and bottom surfaces of the flange portion 190.

The collar 186 may be a single-or multi-piece structure that encircles the dome structure 120 and defines an interior opening that has a nominal diameter larger than the outer diameter of the dome structure 120 just above the flange portion 190 but smaller than the outer diameter of the flange portion 190. The collar 186 may, in some instances, include an internal cooling passage 184 that extends around, at least in part, the dome structure 120. For example, if the collar 186 is a single-piece collar, the cooling passage 184 may extend entirely around, or almost entirely around, the dome structure 120. However, if the collar 186 is a multi-piece collar, e.g., four equal-sized arcuate pieces generally corresponding to a quarter-circle in shape, then each piece may have a separate cooling passage located within it.

Regardless, the cooling passage or cooling passages 184 may, either singly or in the aggregate, extend around the dome structure. During at least cleaning operations, a coolant may be circulated through the cooling passage(s) in order to remove heat from the collar 186 and the adjacent structures, such as the edge of the faceplate 116 and the dome structure 120. This allows the bottom portion of the dome structure 120 to be cooled while the cleaning plasma is being flowed, thereby reducing the rate at which the cleaning plasma that makes it into the enclosed volume 121 etches the material of the dome structure 120.

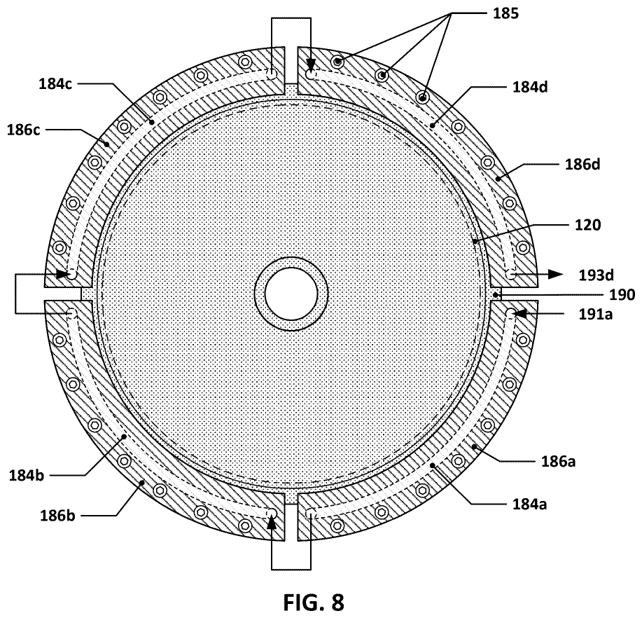

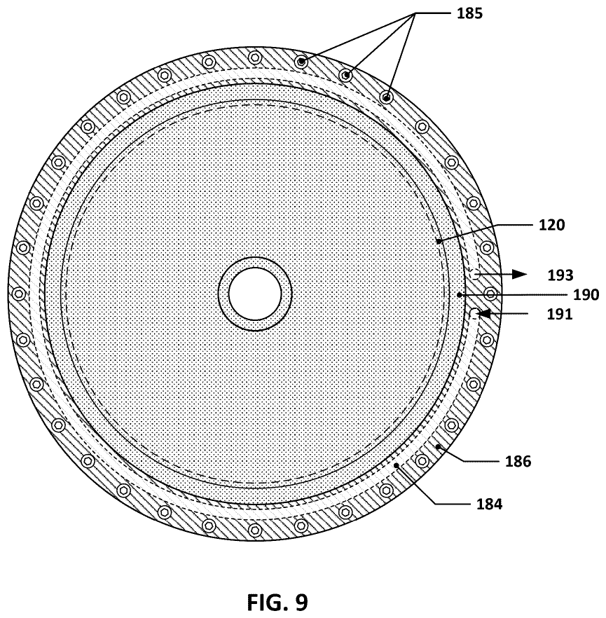

FIG. 8 depicts a top view of an example multi-segment collar clamping a dome structure. As can be seen in FIG. 8, the collar 186 is composed of four equally sized and shaped pieces 186a, 186b, 186c, and 186d, each with a corresponding internal cooling passage 184a, 184b, 184c, and 184d, respectively. Each internal cooling passage 184a, 184b, 184c, and 184d may extend between a respective inlet and outlet. In the depicted example, the internal cooling passages 184a, 184b, 184c, and 184d are connected in series, with the outlet of each of the internal cooling passages 184a, 184b, and 184c connecting with the inlet of the next internal cooling passage 184b, 184c, and 184d, respectively, and with coolant being introduced into the serial flow path via the inlet 191a of the internal cooling passage 184a and received from the internal cooling passages 184 via the outlet 193d of the internal cooling passage 184d. However, in other implementations, each internal cooling passage 184a, 184b, 184c, and 184d may receive coolant in parallel, e.g., the coolant introduced into each internal cooling passage 184a, 184b, 184c, and 184d may be at a generally equal temperature (or at least, not pre-heated by being passed through one of the other internal cooling passages 184a, 184b, 184c, and 184d). Fasteners 185 for clamping the pieces 186a, 186b, 186c, and 186d of the collar 184 are also visible in FIG. 8. FIG. 9 depicts a similar collar 186 that is a contiguous ring and that has a single internal cooling passage 184 that extends around nearly the entire circumference of the dome structure 120. Coolant may be introduced into the internal cooling passage 184 via an inlet 191 and removed via an outlet 193.

Circulation of cooling fluid through the cooling passage 184 and the use of optically transparent quartz for the entire portion of the dome structure 120 that bounds the enclosed volume 121 are to both be understood to reduce the rate at which the dome structure 120 is etched by the cleaning plasma during cleaning plasma flow. However, it will also be understood that the two features may also each be used in isolation, e.g., without the other feature, in some implementations, or may be used not at all (in which case there may be an accelerated rate of dome structure etching.

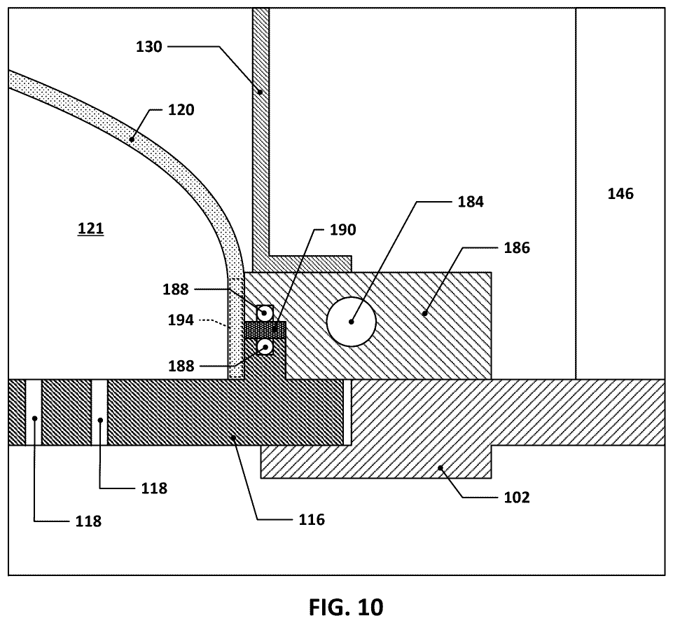

FIG. 10 depicts another example variant in which the flange portion 190 is a separate piece that is made of opaque quartz and is bonded or fused to the remainder of the dome structure 120. The rest of the dome structure 120 is made of optically transparent quartz. In this example, the flange portion 190 blocks all of the ultraviolet light emitted from plasma generated within the enclosed volume 121 from reaching the seals 188.

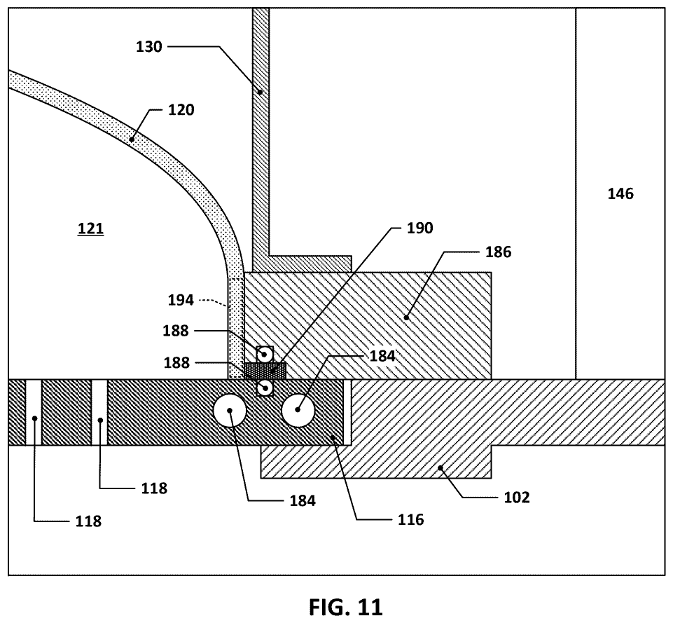

FIG. 11 depicts another example variant in which the faceplate 116 has cooling passage(s) 184. For example, the faceplate 116 may have one or more cooling passages located within it that extend around an outer perimeter of the faceplate 116 proximate the lower seal 188. In this example, the flange portion 190 extends off of the bottom edge of the dome structure 120, thereby causing the flange portion 190 to be directly proximate to the faceplate 116 such that it is in close contact with the portion of the faceplate 116 that has the cooling passage(s) in it, thereby increasing the cooling effectiveness of the cooling passage(s) on the dome structure 120. The flange portion 190 in this example is similar to that in FIG. 10, e.g., a separate, ring-like piece of optically opaque quartz that is fused to or bonded to the remainder of the dome structure, which may be made of optically transparent quartz. In other implementations, the flange portion may instead be as shown in FIG. 7, e.g., optically transparent quartz with a layer or coating of optically opaque material bonded to the top and bottom surfaces thereof.

Regardless of the specific implementation of the dome structure used, it was found that modifying the manufacturing process used to make the dome structure provided beneficial effects in some instances.

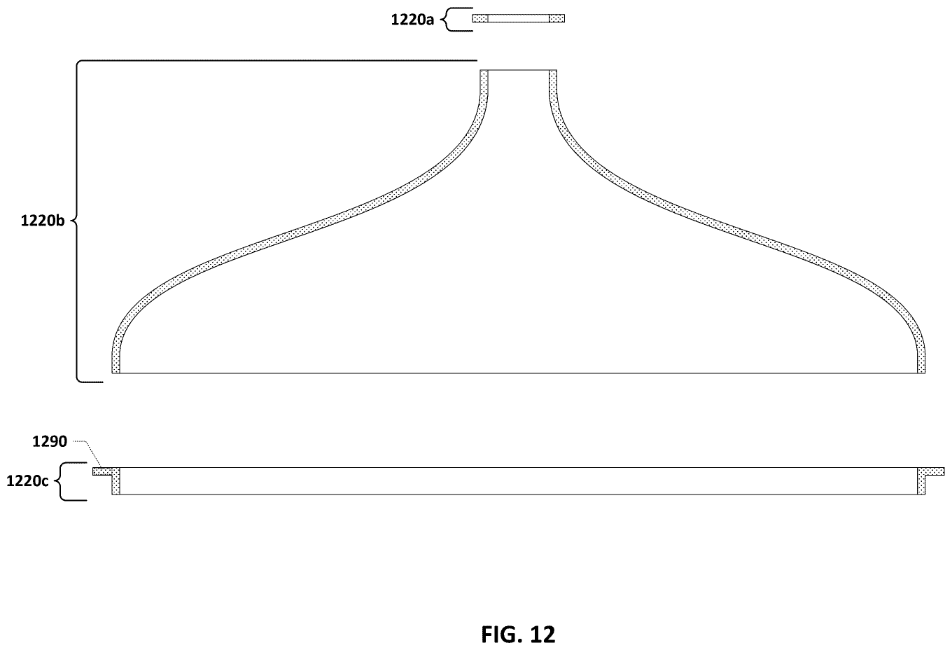

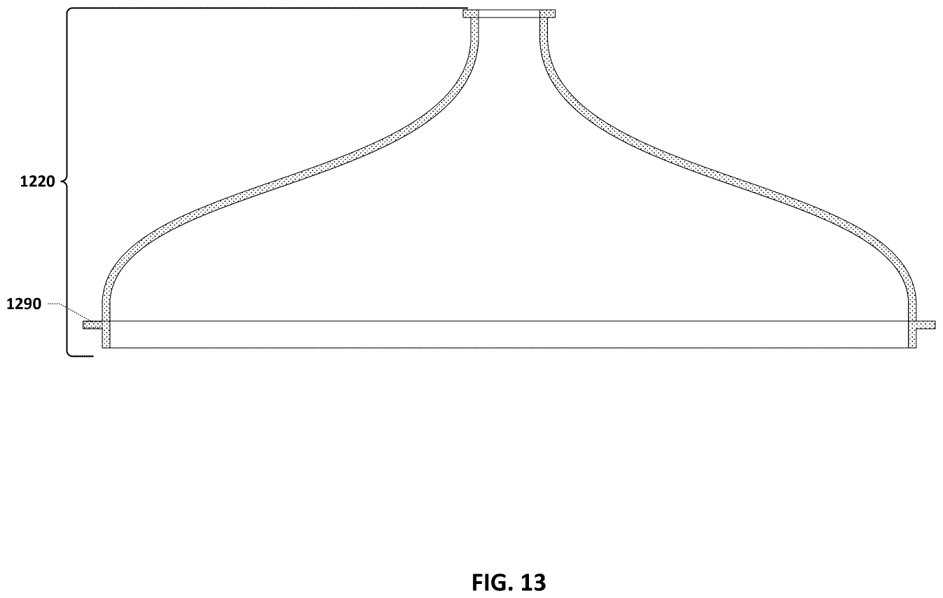

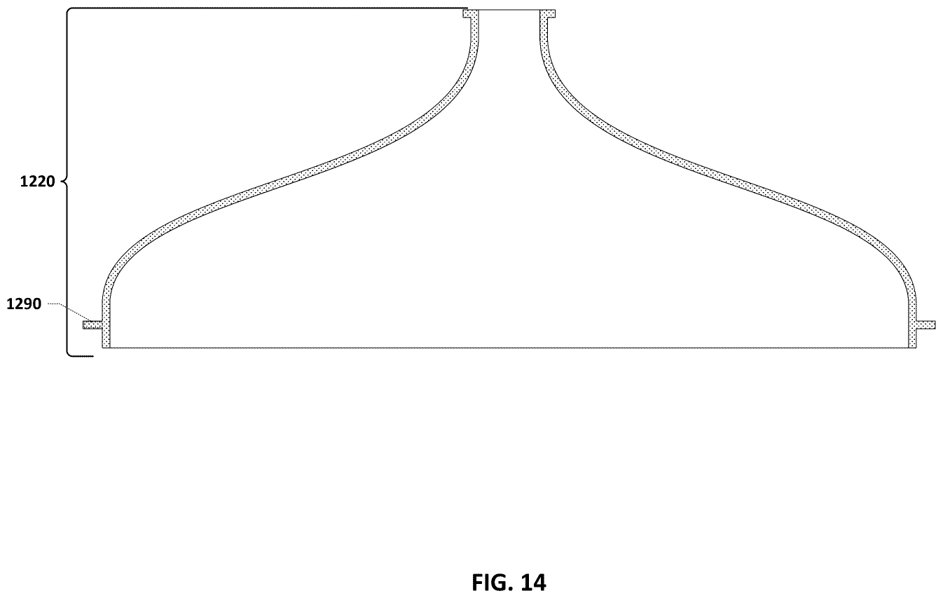

For a dome structure made of quartz, the dome structure may be manufactured using any suitable manufacturing process used for creating quartz parts of such a shape. FIGS. 12 through 16 depict an example of such a dome structure during various phases of manufacture. For example, molten quartz may be subjected to glass-blowing techniques in order to produce the overall shape of the dome structure, and then separately manufactured quartz components, such as flanges provided at the top and bottom of the dome structure, may be fused to the blown portion of the dome structure, e.g., using quartz or glass welding techniques. For example, in FIG. 12, dome structure components 1220a, 1220b, and 1220c are shown as separate pieces. Dome structure components 1220a and 1220c are ring-like components that may provide flanges, such as flange portion 1290, that may be used to interface the resulting dome structure with other components when the dome structure is installed in a semiconductor processing tool, as discussed earlier. Dome structure component 1220b, in contrast, may provide the overall shape of the dome structure and may, for example, be a glass-blown quartz structure. FIG. 13 depicts the assembled dome structure components 1220a, 1220b, and 1220c, which may represent the arrangement of these components prior to them being fused together via a quartz or glass welding operation. FIG. 14 depicts the dome structure that results from the fusion of the dome structure components 1220a, 1220b, and 1220c. The resulting assembled dome structure may then have one or more post-assembly machining operations performed on it, e.g., to machine or grind various surfaces to particular tolerances. For example, the flanges of the dome structure may be machined so as to have flat surfaces where such flanges are intended to mate with other components, such as a faceplate or collar. Once the dome structure has been machined to its final desired form, the dome structure may then be subjected to a flame-polishing operation in order to smooth the surface finish prior to final inspection and installation into the tool.

In some instances, it was found that some quartz dome structures manufactured according to such techniques generated high levels of particulate contamination, e.g., on the order of one hundred to several hundred particulates three microns or larger in size. The present inventors realized that the particulate contamination was significantly mitigated after the installed quartz dome structure was subjected to one or more chamber conditioning operations in which the interior of the dome structure was subjected to an atomic fluorine cleaning process for a significant total period of time, e.g., at least 20 hours in aggregate.

Performing such a conditioning process within the chamber in which the dome structure is installed, however, makes the chamber unavailable for wafer processing operations. It was found that after such a chamber conditioning operation was performed for the aggregate period of time discussed above, the number of particulates three microns or larger that were deposited on a wafer processed using the dome structure dropped into the single digits, e.g., less than ten.

During the conditioning operations, the exposure of the interior of the dome structure to the atomic fluorine gas used in the cleaning processes used during chamber conditioning results in the material of the inward-facing surfaces of the dome structure being etched away. It was found that the amount of material removed from the interior surface of the dome structure during such conditioning operations before the significant reduction in particulate generation was observed was on the order of a thousandth of an inch. The present inventors realized that performing such material removal as part of the dome structure manufacturing process, i.e., prior to installation of the dome structure in the tool/chamber, would provide similar low-particulate generation benefits immediately after installation of the dome structure in the tool, thereby avoiding the need to perform chamber conditioning operations solely to reduce the initial particulate generation rate.

In practice, the manufacturing process of the dome structures generally described above may be modified by including an extra manufacturing step after the dome structures are otherwise complete, e.g., after flame-polishing of the dome structure has been performed. In this extra manufacturing step, the dome structure, or at least the interior surface of the dome structure that would be exposed to processing gas flows when the dome structure is installed in a semiconductor processing tool, may be subjected to an etch process so as to remove a layer of material, e.g., quartz, from the dome structure. In some implementations, the etch process may be designed to remove approximately 0.001″ of material. Such material removal may, for example, represent an average amount of material removal or a minimum amount of material removal. It will be understood that such an etch process may also be designed to remove at least 0.001″ of material but may also remove more than 0.001″ of material. Generally speaking, removal of more than 0.001″ of material will still provide the same beneficial effect but may not appreciably reduce the particulate generation rate beyond the reduction obtained through removal of approximately 0.001″ of material. However, such further material removal will, of course, require additional time (and thus entail additional cost). It will also act to further reduce the total thickness of the dome structure, which may reduce the total lifetime of the dome structure (the dome structure will slowly degrade in thickness during normal processing operations due to the effects of periodic cleaning operations that will need to be performed, resulting in the dome structure needing occasional replacement-if the dome structure is reduced in thickness, this will increase the frequency with which the dome structure needed to be replaced).

At the same time, it is also the case that a reduction in particulate generation may be obtained by etching the dome structure (or at least the interior surface(s) thereof) by less than 0.001″ in the extra manufacturing step. The particulate generation reduction that results from such lesser amounts of material removal will, however, generally be less than what was observed for material removal of approximately 0.001″. Accordingly, it will be understood that the present technique also encompasses such extra manufacturing steps in which less than 0.001″ of material may be removed from the dome structure (or its interior surface(s)). For example, in some implementations, the extra manufacturing step may involve etching away at least 0.0009″, 0.0008″, 0.0007″, 0.0006″, 0.0005″, 0.0004″, or 0.0003″ of material (either at a minimum or on average) from at least interior surface(s) of the dome structure instead of at least 0.001″ of material.

The etching process performed in the extra manufacturing step may be provided by exposing the surface(s) of the dome structure where material removal is to occur to an etchant, such as atomic fluorine or hydrogen fluoride or other substance that is reactive with quartz and capable of etching away the material of the dome structure. The etchant may be provided in either gaseous or liquid form and at a concentration that may be selected to provide the desired amount of material removal within a desired amount of exposure time to the etchant.

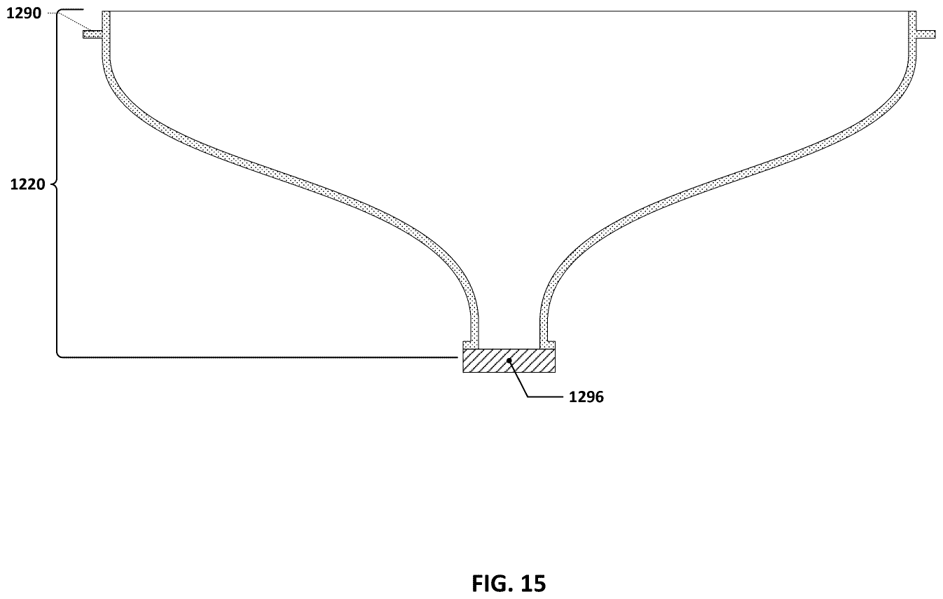

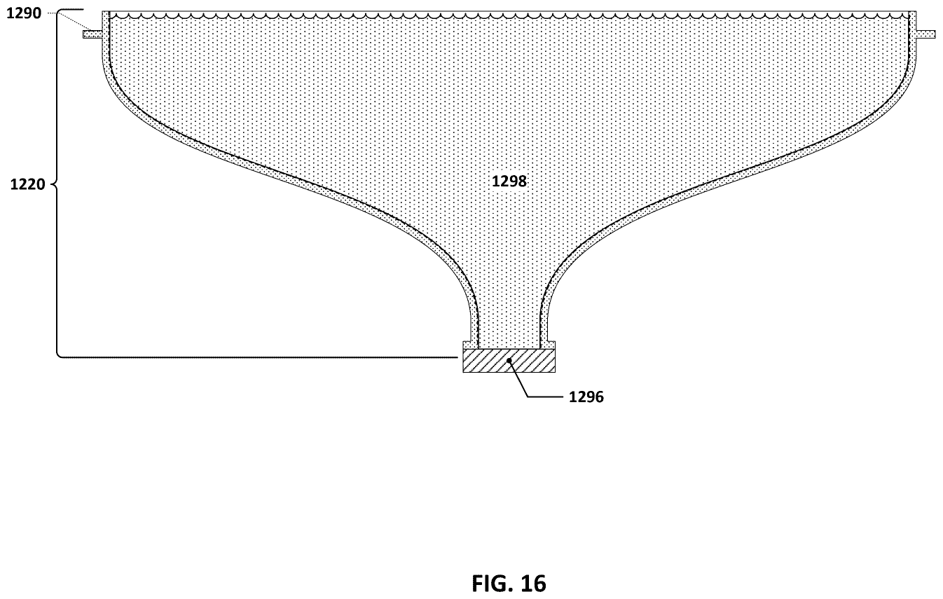

For example, the dome structure may have an open end thereof capped with another component, e.g., a seal plate, so as to form a bowl or other open-topped vessel. FIG. 15 depicts such an arrangement. As can be seen, the dome structure 1220 has been flipped upside-down such that the smaller opening to the dome structure (the “inlet” opening) is facing downward. A cap 1296 has been installed over the smaller opening, turning the dome structure 1220 into an open-faced bowl, in effect. This open-topped vessel may then be filled with an aqueous solution of hydrogen fluoride that is then allowed to stay resident in the dome structure for an extended period of time, e.g., several hours, until the desired amount of material removal has, or has likely, occurred. For example, a 25% molar concentration of hydrofluoric acid (hydrogen fluoride) was found to be able to etch approximately 0.001″ of material from the interior surfaces of a quartz dome structure after three to four hours of exposure (although other concentrations may be used as well, depending on the amount of etching desired and the time frame desired for the etch process). FIG. 16 depicts the upside-down dome structure 1220 of FIG. 15 filled with etchant 1298. The etchant may then be drained and, if desired, one or more measurements taken of the thickness of the dome structure. Such measurements may be compared with similar measurements obtained prior to the etching of the dome structure in order to allow characterization of the thickness of the material layer that is removed by the etchant. If necessary, e.g., if the desired amount of material has not been removed, the dome structure may be re-filled with etchant to further expose the dome structure to the etchant and remove additional material. This procedure may be repeated as necessary until the desired degree of material removal is obtained.

In the case of use of a gas-based etch process during the extra dome structure manufacturing step, the dome structure may instead be sealed at both open ends so as to form an enclosed chamber that can contain the etchant.

It will be understood that once the extra manufacturing step has been performed and the dome structure etched, the dome structure may also be subjected to one or more wash or rinsing operations in order to wash or rinse the exterior of the dome structure of any potential remaining contaminants.

As described above, the extra manufacturing step for the dome structure is performed after the flame-polishing step. It will, however, be appreciated that in other dome structure manufacturing processes, a flame-polishing step may not be performed at all. In such instances, the extra manufacturing step may simply be the last material removal or alteration step performed. However, it may also be the case that in such instances, the amount of material that is removed in the extra manufacturing step may be increased from the recommended 0.001″ of material removal recommended above.

For example, in dome structures that are flame-polished, the flame-polishing has the effect of “evening out” the surface finish of the dome structure. For example, “high points” in the surface structure may become molten and may flow radially outward, thereby resulting in the high points losing altitude, whereas low points in the surface structure may also become molten and may flow radially inward, thereby partially filling recesses associated with the low points. As a result, the variance between the “highest” and “lowest” points on the flame-polished surface (with respect to a midplane of such a surface) may decrease after flame-polishing. This “averaging” effect may, for example, provide some reduction in particulate contamination that may arise with use of a flame-polished dome structure (as compared with non-flame-polished dome structures). If the flame-polishing step is not performed, then the extra manufacturing step of chemically removing a layer of material discussed above may be modified so as to cause more than 0.001″ of material to be removed in order to remove the particulate-formers that would have been removed by the flame-polishing step had it been performed.

It will also be appreciated that the same extra manufacturing step may be used with dome structures that are not multi-piece assemblies but are instead manufactured as a single piece from the start.

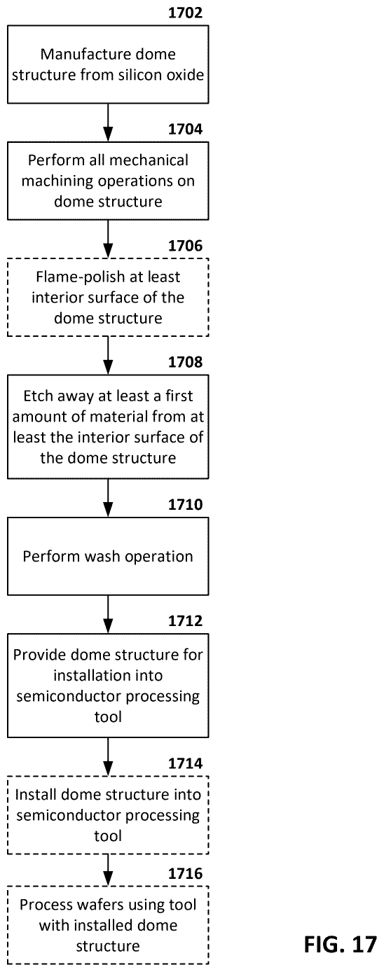

FIG. 17 depicts a high-level flow diagram of the dome structure manufacturing process discussed above. In block 1702, the dome structure may be assembled using any suitable manufacturing process for producing quartz dome structures (either as a multi-piece assembly or a single-piece part). In block 1704, any remaining mechanical machining operations necessary to place the dome structure into its final-machined form may be performed. This may include performing any machining operations that can produce dust particles, such as drilling, cutting, grinding, lapping, etc. In block 1706, the dome structure may be optionally flame-polished, as discussed earlier. Such flame-polishing may, for example, involve exposing the surface(s) of the dome structure to be polished to a high-temperature flame, e.g., greater than 1500° C., in order to soften/melt outermost layer of quartz.

In block 1708, one or more surfaces of the dome structure may be subjected to an etch process, as discussed earlier, in which a layer of quartz is etched away by exposure to a chemical etchant, such as hydrofluoric acid. Such a quartz layer may, for example, be approximately 0.001″ thick, although other thicknesses may be used as well. It is worth noting that if the optional flame-polishing operation of block 1706 is pursued as well, the subsequent etching of the dome structure in block 1708 would, in effect, “undo” the flame polishing operation since the etched surface that results from block 1708 would have a frosted or cloudy appearance, whereas that same surface would, after the flame-polishing and immediately prior to the etching step, have a polished or smooth appearance.

In block 1710, the etched dome structure may be subjected to a wash operation, e.g., in which any chemical residues that may be present may be washed away. In block 1712, the dome structure may be provided, e.g., to a downstream manufacturer of semiconductor processing tools, for installation into a semiconductor processing tool.

Once the dome structure is provided for installation in a semiconductor processing tool, the dome structure may be then installed into such a semiconductor processing tool in block 1714 and the tool then used with the dome structure installed in block 1716 to process one or more semiconductor wafers. Blocks 1714 and 1716 may, it will be recognized, be performed separately from the manufacture of the dome structure itself.

As discussed above, in some implementations, a controller may be part of the apparatuses discussed herein. The controller, depending on the processing requirements and/or the type of system, may be programmed to control any of the processes disclosed herein, such as processes for controlling the movement of actuators, operation of fans, and/or heating provided by heating elements, as well as other processes or parameters not discussed herein, such as the delivery of processing gases, temperature settings (e.g., heating and/or cooling of other components, such as wafer supports), pressure settings, vacuum settings, power settings, radio frequency (RF) generator settings, RF matching circuit settings, frequency settings, flow rate settings, fluid delivery settings, positional and operation settings, wafer transfers into and out of a chamber and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example apparatuses according to the present disclosure may be mounted in or part of semiconductor processing tools with a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

It will be understood that while reference is made above to various systems being able to be operable in different states, modes, etc., such reference is not exclusive to only the various states, modes, etc., that may be listed. For example, a system that is operable in different modes that include a first mode and a second mode is not limited to being operable in only the first or second mode, but may also optionally be operable in a third mode, a fourth mode, etc.

Additionally, the term “including,” “includes,” or the like is understood to be interpreted in an open-ended manner, e.g., in a manner similar to “comprising,” unless explicitly stated to the contrary. For example, an apparatus that includes two threaded fasteners will be understood to not exclude an apparatus that includes three threaded fasteners. However, an apparatus that includes only two threaded fasteners will be understood to exclude an apparatus that includes three threaded fasteners.

The use, if any, of ordinal indicators, e.g., (a), (b), (c) . . . or (1), (2), (3) . . . or the like, in this disclosure and claims is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated) unless indicated otherwise. For example, if step (ii) involves the handling of an element that is created in step (i), then step (ii) may be viewed as happening at some point after step (i). Similarly, if step (i) involves the handling of an element that is created in step (ii), the reverse is to be understood. It is also to be understood that use of the ordinal indicator “first” herein, e.g., “a first item,” should not be read as suggesting, implicitly or inherently, that there is necessarily a “second” instance, e.g., “a second item.”

It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise).

For the purposes of this disclosure, the term “fluidically connected” is used with respect to volumes, plenums, holes, etc., that may be connected with one another, either directly or via one or more intervening components or volumes, in order to form a fluidic connection, similar to how the term “electrically connected” is used with respect to components that are connected together to form an electrical connection. The term “fluidically interposed,” if used, may be used to refer to a component, volume, plenum, or hole that is fluidically connected with at least two other components, volumes, plenums, or holes such that fluid flowing from one of those other components, volumes, plenums, or holes to the other or another of those components, volumes, plenums, or holes would first flow through the “fluidically interposed” component before reaching that other or another of those components, volumes, plenums, or holes. For example, if a pump is fluidically interposed between a reservoir and an outlet, fluid that flowed from the reservoir to the outlet would first flow through the pump before reaching the outlet. The term “fluidically adjacent,” if used, refers to placement of a fluidic element relative to another fluidic element such that there are no potential structures fluidically interposed between the two elements that might potentially interrupt fluid flow between the two fluidic elements. For example, in a flow path having a first valve, a second valve, and a third valve placed sequentially therealong, the first valve would be fluidically adjacent to the second valve, the second valve fluidically adjacent to both the first and third valves, and the third valve fluidically adjacent to the second valve.

The term “between,” as used herein and when used with a range of values, is to be understood, unless otherwise indicated, as being inclusive of the start and end values of that range. For example, between 1 and 5 is to be understood to be inclusive of the numbers 1, 2, 3, 4, and 5, not just the numbers 2, 3, and 4.

The term “operatively connected” is to be understood to refer to a state in which two components and/or systems are connected, either directly or indirectly, such that, for example, at least one component or system can control the other. For example, a controller may be described as being operatively connected with a resistive heating unit, which is inclusive of the controller being connected with a sub-controller of the resistive heating unit that is electrically connected with a relay that is configured to controllably connect or disconnect the resistive heating unit with a power source that is capable of providing an amount of power that is able to power the resistive heating unit so as to generate a desired degree of heating. The controller itself likely cannot supply such power directly to the resistive heating unit due to the currents involved, but it will be understood that the controller is nonetheless operatively connected with the resistive heating unit.

It is understood that the examples and implementations described herein are for illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein but may be modified within the scope of the disclosure.

It is to be understood that the above disclosure, while focusing on a particular example implementation or implementations, is not limited to only the discussed example, but may also apply to similar variants and mechanisms as well, and such similar variants and mechanisms are also considered to be within the scope of this disclosure. The disclosure is, however, at least directed at the following numbered implementations.
Implementation 1: an apparatus comprising:
one or more process stations, each process station including:
   an enclosure defining a cooling volume,
   a dome structure comprising a radio-transmissive material, having an inlet as well as an outlet opposite the inlet, and located within the cooling volume of the enclosure of that process station,
   one or more radio frequency (RF) coils that extend around the dome structure of that process station,
   a faceplate positioned underneath the dome structure of that process station and proximate the outlet of the dome structure of that process station, and
   a wafer support positioned such that the faceplate of that process station is interposed between the wafer support of that process station and the dome structure of that process station;
a cleaning plasma distribution system configured to facilitate direction of a cleaning plasma onto the wafer support or wafer supports of the one or more process stations;
an RF power system configured to be operable in different power modes, the different power modes comprising a first power mode and a second power mode, wherein:
   the RF power system, in the first power mode, provides at least a first level of RF power to the RF coil or RF coils of the one or more process stations,
   the RF power system, in the second power mode, provides a second level of RF power to the RF coil or RF coils of the one or more process stations, and
   the second level of RF power is less than the first level of RF power;
a cooling system configured to be operable in different cooling modes, the different cooling modes comprising a first cooling mode and a second cooling mode, wherein:
   the cooling system, in the first cooling mode, cools the dome structure or dome structures of the one or more process stations at a first rate and using a cooling fluid, and
   the cooling system, in the second cooling mode, cools the dome structure or dome structures of the one or more process stations at a second rate lower than the first rate and using the cooling fluid; and
a controller, the controller configured to cause the apparatus to be operable in different operational modes, the different operational modes comprising at least a first operational mode and a second operational mode, wherein:
   the controller, when causing the apparatus to be operable in the first operational mode, causes the RF power system to be in the first power mode and causes the cooling system to be in the first cooling mode, and
   the controller, when causing the apparatus to be operable in the second operational mode, causes the cleaning plasma distribution system to direct the cleaning plasma onto the one or more wafer supports of the one or more process stations and causes the cooling system to be in the second cooling mode.
Implementation 2: The apparatus of implementation 1, further comprising a flow modulation system configured to be operable in different flow states, the different flow states comprising a first flow state and a second flow state, wherein:
the cooling system comprises an exhaust system interface and one or more conduits, each conduit fluidically interposed between the exhaust system interface and the cooling volume defined by the enclosure of a corresponding one of the one or more process stations, wherein the exhaust system interface is configured to be connected with a facility exhaust system,
the flow modulation system, in the first flow state, permits up to a first level of fluid flow from the cooling volume or cooling volumes defined by the enclosure or enclosures of the one or more process stations and through the exhaust system interface via the one or more conduits,
the flow modulation system, in the second flow state, permits up to a second level of fluid flow from the cooling volume or cooling volumes defined by the enclosure or enclosures of the one or more process stations and through the exhaust system interface via the one or more conduits,
the second level of fluid flow is less than the first level of fluid flow,
the controller, when causing the apparatus to be in the first operational mode, is configured to cause the flow modulation system to be in the first flow state, and
the controller, when causing the apparatus to be in the second operational mode, is configured to cause the flow modulation system to be in the second flow state.
Implementation 3: The apparatus of implementation 2, wherein the second level of fluid flow is 10% or less of the first level of fluid flow.
Implementation 4: The apparatus of implementation 2, wherein the second level of fluid flow is a zero level of fluid flow.
Implementation 5: The apparatus of any of implementations 2 through 4, wherein:
the flow modulation system comprises one or more actuators and one or more movable elements,
the one or more actuators are configured to cause the one or more movable elements to move between at least a first position and a second position when actuated,
the one or more movable elements, when in the first position, provide a first level of flow resistance to fluid flow through the one or more conduits,
the one or more movable elements, when in the second position, provide a second level of flow resistance to fluid flow through the one or more conduits,
the second level of flow resistance is higher than the first level of flow resistance,
the controller, when causing the apparatus to be in the first operational mode, controls the one or more actuators such that the one or more movable elements are in the first position, and
the controller, when causing the apparatus to be in the second operational mode, controls the one or more actuators such that the one or more movable elements are in the second position.
Implementation 6: The apparatus of implementation 5, wherein each movable element of the one or more movable elements is configured so as to at least partially block a flow path through at least one of the one or more conduits when in the second position.
Implementation 7: The apparatus of implementation 5, wherein each movable element of the one or more movable elements is configured so as to completely block a flow path through at least one of the one or more conduits when in the second position.
Implementation 8: The apparatus of any of implementations 5 through 7, wherein:
the flow modulation system comprises one or more vent ports, each vent port leading to an alternate flow path separate from the flow path or flow paths through the one or more conduits; and
each movable element of the one or more movable elements is configured so as to at least partially block at least one of the alternate flow paths when in the first position and to block that at least one of the alternate flow paths to a lesser extent when in the second position.
Implementation 9: The apparatus of any of implementations 5 through 7, wherein:
the flow modulation system comprises one or more vent ports, each vent port leading to an alternate flow path separate from the flow path or flow paths through the one or more conduits; and
each movable element of the one or more movable elements is configured so as to completely block at least one of the alternate flow paths when in the first position and to not block that at least one of the alternate flow paths when in the second position.
Implementation 10: The apparatus of implementation 9, wherein:
the one or more vent ports are fluidically interposed between the exhaust system interface and an ambient environment, and
the one or more alternate flow paths lead to the ambient environment.
Implementation 11: The apparatus of any of implementations 5 through 10, wherein each movable element is a shutter.
Implementation 12: The apparatus of implementation 11, wherein the flow modulation system is located in the exhaust system interface.
Implementation 13: The apparatus of implementation 12, wherein:
the one or more process stations comprises multiple process stations,
the exhaust system interface comprises a housing having one or more walls with one or more first openings and one or more second openings, each first opening leading to one of the conduits and each second opening serving as one of the one or more vent ports or as a vent port, and
the one or more movable elements comprise a movable element that is a shutter that is sized so as to block all of the one or more second openings and none of the one or more first openings when in the first position and so as to block all of the one or more first openings and none of the one or more second openings when in the second position.
Implementation 14: The apparatus of any of implementations 1 through 13, wherein:
each enclosure has one or more first apertures and one or more first fans, each first fan positioned proximate to one of the first apertures,
the controller is configured to cause the one or more first fans of each enclosure to operate at a first fan speed when causing the apparatus to be in the first operational mode,
the controller is configured to cause the one or more first fans of each enclosure to operate at a second fan speed when causing the apparatus to be in the second operational mode, and
the second fan speed is lower than the first fan speed.
Implementation 15: The apparatus of implementation 14, wherein the second fan speed is 10% or less of the first fan speed.
Implementation 16: The apparatus of implementation 14, wherein the second fan speed is zero.
Implementation 17: The apparatus of any of implementations 1 through 13, wherein:
each enclosure has one or more first apertures, one or more first fans, and one or more fan shutters,
each first fan is positioned proximate to one of the first apertures,
each fan shutter is configured to be movable between a first configuration and a second configuration to adjust a volumetric flow of the cooling fluid into the cooling volume of the enclosure of which that fan shutter is part of,
each fan shutter, in the first configuration, permits up to a first level of the volumetric flow of the cooling fluid,
each fan shutter, in the second configuration, permits up to a second level of the volumetric flow of the cooling fluid,
the first level of the volumetric flow is larger than the second level of the volumetric flow,
the controller is configured to cause the one or more fan shutters be in the first configuration when causing the apparatus to be in the first operational mode, and
the controller is configured to cause the one or more fan shutters be in the second configuration when causing the apparatus to be in the second operational mode.
Implementation 18: The apparatus of implementation 17, wherein the second level of the volumetric flow is 10% or less of the first level of the volumetric flow.
Implementation 19: The apparatus of implementation 17, wherein the second level of the volumetric flow is zero.
Implementation 20: The apparatus of any of implementations 14 through 19, wherein:
each enclosure has one or more inlet-outlet apertures and one or more reversible-direction fans, each reversible-direction fan positioned proximate to one of the inlet-outlet apertures and configured to direct the cooling fluid through the inlet-outlet aperture proximate thereto in a first direction when caused to operate in a first directional mode and to direct the cooling fluid through the inlet-outlet aperture proximate thereto in a direction opposite the first direction when caused to operate in a second directional mode,
the controller is configured to cause the one or more reversible-direction fans to operate in the first directional mode when causing the apparatus to be in the first operational mode, and
the controller is configured to cause the one or more reversible-direction fans to operate in the second directional mode when causing the apparatus to be in the second operational mode.
Implementation 21: The apparatus of any of implementations 1 through 20, wherein:
the cooling system comprises one or more heaters configured to be operable in different heating states, the different heating states comprising a first heating state and a second heating state,
each heater is associated with one of the one or more process stations and is configured to deliver a first amount of heating power to the dome structure of that process station when in the first heating state and a second amount of heating power to the dome structure of that process station when in the second heating state,
the first amount of heating power is less than the second amount of heating power, and
the controller is configured to cause the one or more heaters to be in the first heating state when the cooling system is in the first cooling mode and in the second heating state when the cooling system is in the second cooling mode.
Implementation 22: The apparatus of any of implementations 1 through 20, wherein:
the cooling system comprises one or more heaters configured to be operable in different heating states, the different heating states comprising a first heating state and a second heating state,
each heater is associated with one of the one or more process stations and is configured to deliver, when in a first heating state, a first amount of heating power to the cooling fluid before the cooling fluid is flowed through the cooling volume of that process station and, when in a second heating state, a second amount of heating power to the cooling fluid before the cooling fluid is flowed through the cooling volume of that process station,
the first amount of heating power is less than the second amount of heating power, and
the controller is configured to cause the one or more heaters to be in the first heating state when the cooling system is in the first cooling mode and in the second heating state when the cooling system is in the second cooling mode.
Implementation 23: The apparatus of either of implementations 21 or 22, wherein the first amount of heating power is 10% or less of the second amount of heating power.
Implementation 24: The apparatus of either of implementations 21 or 22, wherein the first amount of heating power is zero.
Implementation 25: The apparatus of any of implementations 1 through 24, wherein the cooling fluid is air.
Implementation 26: The apparatus of implementation 25, wherein the cooling fluid source is ambient air.
Implementation 27: The apparatus of any of implementations 1 through 26, wherein the second level of RF power is a zero power level.
Implementation 28: The apparatus of any of implementations 1 through 27, wherein the second rate is a zero rate.
Implementation 29: An apparatus comprising:
a dome structure having a flange portion extending radially outward from a sidewall of the dome structure, wherein:
the dome structure comprises one or more silicon oxide materials,
the flange portion has a top surface and a bottom surface on a side opposite the top surface, and
a majority of the dome structure has a first transmissivity to ultraviolet light and at least the top surface and the bottom surface have a second transmissivity to ultraviolet light that is lower than the first transmissivity to ultraviolet light.
Implementation 30: The apparatus of implementation 29, wherein:
the flange portion comprises a sub-portion comprising a first silicon oxide material that has the first transmissivity to ultraviolet light,
the sub-portion is covered on top and bottom with a second silicon oxide material that has the second transmissivity to ultraviolet light, and
the second silicon oxide material provides the top surface and the bottom surface.
Implementation 31: The apparatus of implementation 30, wherein the second silicon oxide material is optically opaque to ultraviolet light.
Implementation 32: The apparatus of implementation 31, wherein the second silicon oxide material has microbubbles distributed within it.
Implementation 33: The apparatus of any of implementations 30 through 32, wherein the second silicon oxide material is provided by thin annular rings comprising the second silicon oxide material that are fused to the top and bottom of the sub-portion.
Implementation 34: The apparatus of implementation 29, wherein:
a majority of the dome structure, inclusive of the sidewall, comprises a first silicon oxide material having the first transmissivity to ultraviolet light,
the flange portion comprises a second silicon oxide material having the second transmissivity to ultraviolet light, and
the flange portion is a separate component that is fused to the sidewall.
Implementation 35: The apparatus of any of implementations 29 through 34, further comprising a faceplate, a collar, a first seal, and a second seal, wherein:
the first seal is compressed between the faceplate and the bottom surface of the flange portion, and
the second seal is compressed between the collar and the top surface of the flange portion.
Implementation 36: The apparatus of implementation 35, wherein the faceplate has a plurality of gas distribution ports extending therethrough.
Implementation 37: The apparatus of either implementation 35 or implementation 36, wherein the first seal and the second seal are elastomeric seals.
Implementation 38: The apparatus of any of implementations 35 through 37, wherein the collar is a multi-piece collar comprising multiple segments that encircle the dome structure proximate the flange portion.
Implementation 39: The apparatus of any of implementations 29 through 38, wherein the faceplate comprises one or more internal cooling passages that are proximate to the first seal.
Implementation 40: The apparatus of implementation 39, wherein the one or more internal cooling passages are each arranged so as to follow an arcuate or circular path within the faceplate.
Implementation 41: The apparatus of implementation 40, wherein the bottom surface of the flange portion provides a bottommost surface of the dome structure.
Implementation 42: A method comprising:
manufacturing a silicon oxide dome structure having an inlet as well as an outlet opposite the inlet; and
etching at least an interior surface of the dome structure to remove at least a first amount of silicon oxide material prior to installation of the dome structure in a semiconductor processing tool.
Implementation 43: The method of implementation 42, wherein the first amount is 0.0003″.
Implementation 44: The method of implementation 42, wherein the first amount is 0.0005″.
Implementation 45: The method of implementation 42, wherein the first amount is 0.0007″.
Implementation 46: The method of implementation 42, wherein the first amount is 0.0009″.
Implementation 47: The method of implementation 42, wherein the first amount is 0.001″.
Implementation 48: The method of implementation 42, further comprising subjecting at least the interior surface of the dome structure to a flame-polishing operation prior to the etching of at least the interior surface of the dome structure.
Implementation 49: The method of any of implementations 42 through 48, wherein the etching is performed by exposing at least the interior surface of the dome structure to a gas containing one or both of atomic fluorine and hydrogen fluoride.
Implementation 50: The method of any of implementations 42 through 49, wherein the etching is performed by exposing at least the interior surface of the dome structure to a liquid containing hydrogen fluoride.

The above implementations are, of course, not an exclusive list of the implementations that are discussed in, and apparent from, this disclosure.

1. An apparatus for performing semiconductor processing operations, the apparatus comprising:
one or more process stations, each process station including:
an enclosure defining a cooling volume,
a dome structure comprising a radio-transmissive material, having an inlet as well as an outlet opposite the inlet, and located within the cooling volume of the enclosure of that process station,
one or more radio frequency (RF) coils that extend around the dome structure of that process station,
a faceplate positioned underneath the dome structure of that process station and proximate the outlet of the dome structure of that process station, and
a wafer support positioned such that the faceplate of that process station is interposed between the wafer support of that process station and the dome structure of that process station;
a cleaning plasma distribution system configured to facilitate direction of a cleaning plasma onto the wafer support or wafer supports of the one or more process stations;
an RF power system configured to be operable in different power modes, the different power modes comprising a first power mode and a second power mode, wherein:
the RF power system, in the first power mode, provides at least a first level of RF power to the RF coil or RF coils of the one or more process stations,
the RF power system, in the second power mode, provides a second level of RF power to the RF coil or RF coils of the one or more process stations, and
the second level of RF power is less than the first level of RF power;
a cooling system configured to be operable in different cooling modes, the different cooling modes comprising a first cooling mode and a second cooling mode, wherein:
the cooling system, in the first cooling mode, cools the dome structure or dome structures of the one or more process stations at a first rate and using a cooling fluid, and
the cooling system, in the second cooling mode, cools the dome structure or dome structures of the one or more process stations at a second rate lower than the first rate and using the cooling fluid; and
a controller, the controller configured to cause the apparatus to be operable in different operational modes, the different operational modes comprising at least a first operational mode and a second operational mode, wherein:
the controller, when causing the apparatus to be operable in the first operational mode, causes the RF power system to be in the first power mode and causes the cooling system to be in the first cooling mode, and
the controller, when causing the apparatus to be operable in the second operational mode, causes the cleaning plasma distribution system to direct the cleaning plasma onto the one or more wafer supports of the one or more process stations and causes the cooling system to be in the second cooling mode.

2. The apparatus of claim 1, further comprising a flow modulation system configured to be operable in different flow states, the different flow states comprising a first flow state and a second flow state, wherein:
the cooling system comprises an exhaust system interface and one or more conduits, each conduit fluidically interposed between the exhaust system interface and the cooling volume defined by the enclosure of a corresponding one of the one or more process stations, wherein the exhaust system interface is configured to be connected with a facility exhaust system,
the flow modulation system, in the first flow state, permits up to a first level of fluid flow from the cooling volume or cooling volumes defined by the enclosure or enclosures of the one or more process stations and through the exhaust system interface via the one or more conduits,
the flow modulation system, in the second flow state, permits up to a second level of fluid flow from the cooling volume or cooling volumes defined by the enclosure or enclosures of the one or more process stations and through the exhaust system interface via the one or more conduits,
the second level of fluid flow is less than the first level of fluid flow,
the controller, when causing the apparatus to be in the first operational mode, is configured to cause the flow modulation system to be in the first flow state, and
the controller, when causing the apparatus to be in the second operational mode, is configured to cause the flow modulation system to be in the second flow state.

3. The apparatus of claim 2, wherein the second level of fluid flow is 10% or less of the first level of fluid flow.

4. The apparatus of claim 2, wherein the second level of fluid flow is a zero level of fluid flow.

5. The apparatus of claim 2, wherein:
the flow modulation system comprises one or more actuators and one or more movable elements,
the one or more actuators are configured to cause the one or more movable elements to move between at least a first position and a second position when actuated,
the one or more movable elements, when in the first position, provide a first level of flow resistance to fluid flow through the one or more conduits,
the one or more movable elements, when in the second position, provide a second level of flow resistance to fluid flow through the one or more conduits,
the second level of flow resistance is higher than the first level of flow resistance,
the controller, when causing the apparatus to be in the first operational mode, controls the one or more actuators such that the one or more movable elements are in the first position, and
the controller, when causing the apparatus to be in the second operational mode, controls the one or more actuators such that the one or more movable elements are in the second position.

6. The apparatus of claim 5, wherein each movable element of the one or more movable elements is configured so as to at least partially block a flow path through at least one of the one or more conduits when in the second position.

7. The apparatus of claim 5, wherein each movable element of the one or more movable elements is configured so as to completely block a flow path through at least one of the one or more conduits when in the second position.

8. The apparatus of claim 5, wherein:
the flow modulation system comprises one or more vent ports, each vent port leading to an alternate flow path separate from the flow path or flow paths through the one or more conduits; and
each movable element of the one or more movable elements is configured so as to at least partially block at least one of the alternate flow paths when in the first position and to block that at least one of the alternate flow paths to a lesser extent when in the second position.

9. The apparatus of claim 5, wherein:
the flow modulation system comprises one or more vent ports, each vent port leading to an alternate flow path separate from the flow path or flow paths through the one or more conduits; and
each movable element of the one or more movable elements is configured so as to completely block at least one of the alternate flow paths when in the first position and to not block that at least one of the alternate flow paths when in the second position.

10. The apparatus of claim 9, wherein:
the one or more vent ports are fluidically interposed between the exhaust system interface and an ambient environment, and
the one or more alternate flow paths lead to the ambient environment.

11. The apparatus of claim 8, wherein each movable element is a shutter.

12. The apparatus of claim 11, wherein the flow modulation system is located in the exhaust system interface.

13. The apparatus of claim 12, wherein:
the one or more process stations comprises multiple process stations,
the exhaust system interface comprises a housing having one or more walls with one or more first openings and one or more second openings, each first opening leading to one of the conduits and each second opening serving as one of the one or more vent ports or as a vent port, and
the one or more movable elements comprise a movable element that is a shutter that is sized so as to block all of the one or more second openings and none of the one or more first openings when in the first position and so as to block all of the one or more first openings and none of the one or more second openings when in the second position.

14. The apparatus of claim 1, wherein:
each enclosure has one or more first apertures and one or more first fans, each first fan positioned proximate to one of the first apertures,
the controller is configured to cause the one or more first fans of each enclosure to operate at a first fan speed when causing the apparatus to be in the first operational mode,
the controller is configured to cause the one or more first fans of each enclosure to operate at a second fan speed when causing the apparatus to be in the second operational mode, and
the second fan speed is lower than the first fan speed.

15. The apparatus of claim 14, wherein:
each enclosure has one or more inlet-outlet apertures and one or more reversible-direction fans, each reversible-direction fan positioned proximate to one of the inlet-outlet apertures and configured to direct the cooling fluid through the inlet-outlet aperture proximate thereto in a first direction when caused to operate in a first directional mode and to direct the cooling fluid through the inlet-outlet aperture proximate thereto in a direction opposite the first direction when caused to operate in a second directional mode,
the controller is configured to cause the one or more reversible-direction fans to operate in the first directional mode when causing the apparatus to be in the first operational mode, and
the controller is configured to cause the one or more reversible-direction fans to operate in the second directional mode when causing the apparatus to be in the second operational mode.

16. The apparatus of claim 1, wherein:
each enclosure has one or more first apertures, one or more first fans, and one or more fan shutters,
each first fan is positioned proximate to one of the first apertures,
each fan shutter is configured to be movable between a first configuration and a second configuration to adjust a volumetric flow of the cooling fluid into the cooling volume of the enclosure of which that fan shutter is part of,
each fan shutter, in the first configuration, permits up to a first level of the volumetric flow of the cooling fluid,
each fan shutter, in the second configuration, permits up to a second level of the volumetric flow of the cooling fluid,
the first level of the volumetric flow is larger than the second level of the volumetric flow,
the controller is configured to cause the one or more fan shutters be in the first configuration when causing the apparatus to be in the first operational mode, and
the controller is configured to cause the one or more fan shutters be in the second configuration when causing the apparatus to be in the second operational mode.

17. The apparatus of claim 1, wherein:
the cooling system comprises one or more heaters configured to be operable in different heating states, the different heating states comprising a first heating state and a second heating state,
each heater is associated with one of the one or more process stations and is configured to deliver a first amount of heating power to the dome structure of that process station when in the first heating state and a second amount of heating power to the dome structure of that process station when in the second heating state,
the first amount of heating power is less than the second amount of heating power, and
the controller is configured to cause the one or more heaters to be in the first heating state when the cooling system is in the first cooling mode and in the second heating state when the cooling system is in the second cooling mode.

18. The apparatus of claim 1, wherein:
the cooling system comprises one or more heaters configured to be operable in different heating states, the different heating states comprising a first heating state and a second heating state,
each heater is associated with one of the one or more process stations and is configured to deliver, when in a first heating state, a first amount of heating power to the cooling fluid before the cooling fluid is flowed through the cooling volume of that process station and, when in a second heating state, a second amount of heating power to the cooling fluid before the cooling fluid is flowed through the cooling volume of that process station,
the first amount of heating power is less than the second amount of heating power, and
the one or more heaters are caused to be in the first heating state when the cooling system is in the first cooling mode and in the second heating state when the cooling system is in the second cooling mode.

19. An apparatus for use in semiconductor processing, the apparatus comprising:
a dome structure having a flange portion extending radially outward from a sidewall of the dome structure, wherein:
the dome structure comprises one or more silicon oxide materials,
the flange portion has a top surface and a bottom surface on a side opposite the top surface, and
a majority of the dome structure has a first transmissivity to ultraviolet light and at least the top surface and the bottom surface have a second transmissivity to ultraviolet light that is lower than the first transmissivity to ultraviolet light.

20. A method of manufacturing a dome structure for use in semiconductor processing equipment, the method comprising:
manufacturing a silicon oxide dome structure having an inlet as well as an outlet opposite the inlet; and
etching at least an interior surface of the dome structure to remove at least a first amount of silicon oxide material prior to installation of the dome structure in a semiconductor processing tool.
